(19) United States
(12) Patent Application Publication
(10) Pub. No.: US 2020/0113048 A1
(43) Pub. Date: Apr. 9, 2020

(54) METHOD FOR PRODUCING LAMINATED BODY, LAMINATED BODY AND METHOD FOR PRODUCING FLEXIBLE PRINTED CIRCUIT BOARD

(71) Applicant: AGC Inc., Chiyoda-ku (JP)

(72) Inventors: Wataru KASAI, Chiyoda-ku (JP); Seigo KOTERA, Chiyoda-ku (JP)

(73) Assignee: AGC Inc., Chiyoda-ku (JP)

(21) Appl. No.: 16/710,064

(22) Filed: Dec. 11, 2019

Related U.S. Application Data
(63) Continuation of application No. PCT/JP2018/016666, filed on Apr. 24, 2018.

(30) Foreign Application Priority Data
Jul. 7, 2017 (JP) 2017-133883
Oct. 2, 2017 (JP) 2017-193094

(51) Int. Cl. H05K 1/03; B32B 38/10; H05K 3/38; B32B 15/08

(52) U.S. Cl. CPC H05K 1/0393; B32B 38/10; B32B 2457/08; B32B 15/08; H05K 3/38

(57) ABSTRACT

To provide a laminated body in which wrinkles and delamination are suppressed, a method for its production, and a method for producing a flexible printed circuit board in which occurrence of wrinkles and delamination is suppressed. A method for producing a laminated body comprises disposing, on one side or both sides of a first substrate composed of either one or both of a heat-resistant substrate layer and a metal foil layer, a second substrate containing a fluororesin and having a first surface of which the wetting tension is from 30 to 60 mN/m and a second surface of which the wetting tension is smaller by at least 2 mN/m than the wetting tension of the first surface, so that the first surface faces the first substrate side; and while transporting the first substrate and the second substrate, pressing them in the thickness direction at a temperature T₁ of from 0 to 100° C. for lamination, to obtain a laminated body I in which the first substrate and the second substrate are directly laminated.

This application is a continuation of PCT Application No. PCT/JP2018/016666, filed on Apr. 24, 2018, which is based upon and claims the benefit of priority from Japanese Patent Application No. 2017-133883 filed on Jul. 7, 2017 and Japanese Patent Application No. 2017-193094 filed on Oct. 2, 2017. The contents of those applications are incorporated herein by reference in their entireties.

### TECHNICAL FIELD

The present invention relates to a method for producing a laminated body in which wrinkles and delamination are suppressed, a laminated body, and a method for producing a flexible printed circuit board.

### BACKGROUND ART

A laminated body of a fluororesin and another material, is preferably used as e.g. a base material of a flexible printed circuit board, an electromagnetic wave shielding tape of a cable, a laminated type bag for a lithium ion battery, etc. by making use of heat resistance, electrical properties, chemical resistance, etc. inherent to the fluororesin.

As a common method for producing a laminated body of a fluororesin and another material, a heat lamination method may be mentioned. This technique is a technique in which two or more thin-film form materials are conveyed by roll-to-roll, and pressed while being heated at least at a temperature where at least one side of the thin-film form materials is softened (or molten), to bond the two or more thin-film form materials. However, in a case where the above laminated body is to be produced by the heat lamination method, there have been problems such that due to the lack of stiffness and low strength because of a low elastic modulus of the fluororesin, wrinkles may occur in the fluororesin layer, or the fluororesin layer may be broken at the time of bonding.

As a method for producing a laminated body of a fluororesin and another material, the following methods have been proposed.

(1) A method of laminating a fluororesin film having discharge treatment applied to both surfaces, on one surface of a film of an aromatic polyimide having discharge treatment applied to both surfaces (Patent Document 1).

(2) A method of bonding a polyimide film and a fluororesin film, by applying a load by a heated roll, and then subjecting them to annealing treatment at a temperature of at least the melting point of the fluororesin (Patent Document 2).

(3) A method of heat-laminating a fluororesin film containing a fluororesin having specific functional groups and a metal foil, below the melting point of the fluororesin, and heat-laminating the fluororesin film of the obtained fluororesin layer-attached metal foil and a heat resistant resin film at a temperature of at least the melting point of the fluororesin (Patent Document 3).

### PRIOR ART DOCUMENTS

### Patent Documents

Patent Document 1: JP-B-H5-59828

Patent Document 2: JP-A-2016-87799

Patent Document 3: WO2016/104297

### DISCLOSURE OF INVENTION

### Technical Problem

In the methods in Patent Documents 1 to 3, a fluororesin and another material are temporarily laminated at a temperature lower than the melting point of the fluororesin, and then, principally laminated at a temperature of at least the melting point of the fluororesin. Since the temperature for the temporary lamination is lower than the melting point of the fluororesin, as compared to a case where the principal lamination is conducted without the temporary lamination, wrinkles of the fluororesin layer is suppressed.

However, the temporary lamination temperature used in Patent Documents 1 to 3 is still a high temperature, whereby wrinkles of the fluororesin layer cannot be sufficiently suppressed. Further, the laminated body after the temporary lamination (temporarily laminated body) may sometimes be curled.

According to the studies made by the present inventors, in the methods in Patent Documents 1 to 3, if the temporary lamination is conducted at a lower temperature, the fluororesin layer and another material layer will not be bonded and no temporarily laminated body will be obtained, or even if a temporarily laminated body is obtained, there will be a problem such that the fluororesin layer and another material layer adjacent thereto are partially peeled, and air is likely to enter. Wrinkles or peeling at the temporarily laminated body will also remain after the principal lamination.

An object of the present invention is to provide a laminated body in which wrinkles and delamination are suppressed, a method for its production, and a method for producing a flexible printed circuit board, in which occurrence of wrinkles and delamination is suppressed.

### Solution to Problem

The present invention has the following embodiments.

[1] A method for producing a laminated body, which comprises disposing, on one side or both sides of a first substrate composed of either one or both of a heat-resistant substrate layer and a metal foil layer, a second substrate containing a fluororesin and having a first surface of which the wetting tension as measured in accordance with JIS K6768:1999 is from 30 to 60 mN/m and a second surface of which said wetting tension is smaller by at least 2 mN/m than the wetting tension of the first surface, so that said first surface faces said first substrate side, and, while transporting the first substrate and the second substrate, pressing them in the thickness direction at a temperature T₁ of from 0 to 100° C. for lamination, to obtain a laminated body I wherein the first substrate and the second substrate are directly laminated.
[2] The method for producing a laminated body according to [1], which comprises disposing, on the second substrate of the laminated body I, a third substrate composed of either one or both of a heat-resistant substrate layer and a metal foil layer, and, while transporting the laminated body I and the third substrate, pressing them in the thickness direction at a temperature T₂ of at least the melting point of the fluororesin for lamination, to obtain a laminated body II wherein the laminated body I and the third substrate are directly laminated.
[3] The method for producing a laminated body according to [1] or [2], wherein the control of the wetting tension of the second substrate of the laminated body I is carried out by surface treatment, and the method for the surface treatment is by corona discharge treatment or vacuum plasma treatment.
[4] The method for producing a laminated body according to any one of [1] to [3], wherein at the time of transporting the first substrate and the second substrate, the elongation obtainable by the following formula 1, of each of the first substrate and the second substrate, is made to be from 0.05 to 1.0%, and the difference in the elongation between the first substrate and the second substrate is made to be at most 0.3%:

elongation (%)={tension (N) applied to the substrate during transportation/cross-sectional area (mm²) of the substrate in a direction perpendicular to the transporting direction}/elastic modulus (N/mm²) of the substrate at a temperature T₁×100 Formula 1:

[5] The method for producing a laminated body according to any one of [1] to [4], wherein the pressing force at the time of laminating the first substrate and the second substrate is from 3 to 100 kN/m.

[6] The method for producing a laminated body according to any one of [1] to [5], wherein at either one or both of a terminal group of the main chain and a pendant group of the main chain of the fluororesin, at least one type of functional group selected from the group consisting of a carbonyl group-containing group, a hydroxy group, an epoxy group, an amide group, an amino group and an isocyanate group is present.
[7] The method for producing a laminated body according to any one of [1] to [6], wherein the first substrate is a heat-resistant resin film, and the water contact angle of its surface as measured by the sessile drop method described in JIS R6769:1999, is from 5° to 60°.
[8] The method for producing a laminated body according to [7], wherein the heat-resistant resin film is a film which is surface-treated by corona discharge treatment, atmospheric pressure plasma treatment or vacuum plasma treatment.
[9] The method for producing a laminated body according to [7] or [8], wherein the water absorption of the heat-resistant resin film is at most 1.5%.
[10] A laminated body in which, on one side or both sides of a first substrate composed of either one or both of a heat-resistant substrate layer and a metal foil layer, a second substrate containing a fluororesin and having a first surface of which the wetting tension as measured in accordance with JIS K6768:1999 is from 30 to 60 mN/m and a second surface of which said wetting tension is smaller by at least 2 mN/m than the wetting tension of the first surface, is laminated directly, so that the first surface faces the first substrate side.
[11] A method for producing a flexible printed circuit board, which comprises obtaining the laminated body II of which at least one of the outermost layers is a metal foil layer, by the method for producing a laminated body as defined in claim 2, and removing a portion of the metal foil layer of the outermost layers by etching to form a patterned circuit.

### Advantageous Effects of Invention

According to the method for producing a laminated body of the present invention, it is possible to produce continuously and stably a laminated body in which occurrence of wrinkles, curling and delamination is suppressed. In the laminated body of the present invention, occurrence of wrinkles, curling and delamination is suppressed. According to the method for producing a flexible printed circuit board of the present invention, it is possible to produce a flexible printed circuit board in which occurrence of wrinkles, curling and delamination is suppressed.

### BRIEF DESCRIPTION OF THE DRAWINGS

FIG. 1 is a schematic cross-sectional view showing an example of the laminated body I.

FIG. 2 is a schematic cross-sectional view showing an example of the laminated body II.

FIG. 3 is a schematic cross-sectional view showing another example of the laminated body I.

FIG. 4 is a schematic cross-sectional view showing another example of the laminated body II.

FIG. 5 is a schematic diagram showing a laminating apparatus used in the first embodiment of the present invention.

FIG. 6 is a schematic diagram showing a laminating apparatus used in the second embodiment of the present invention.

FIG. 7 is a schematic diagram showing a laminating apparatus used in the third embodiment of the present invention.

FIG. 8 is a diagram illustrating the method for evaluation of curling in Examples.

### DESCRIPTION OF EMBODIMENTS

In this specification, the meanings of the following terms are as follows.

The “melting point” means the temperature corresponding to the maximum value of the melting peak as measured by a differential scanning calorimetry (DSC) method.

The “wetting tension” is a value measured in accordance with JIS K6768:1999. In the measurement of the wetting tension, on a test specimen, a cotton swab soaked with a test liquid having a known wetting tension is quickly rubbed, to form a liquid film of 6 cm², and the state of the liquid film after 2 seconds from the application is observed, whereby a case where no breakage is observed, is regarded as wetting. The maximum wetting tension where no breakage of the liquid film is observed, is adopted as the wetting tension of the test specimen. Here, the lower limit of the wetting tension of a test liquid as specified in JIS K6768:1999 is 22.6 mN/m.

The “thermal expansion/contraction ratio” refers to values in both the flow direction (MD) and the direction (TD) orthogonal to the flow direction, as measured by the method specified in IS011501:1995, under conditions of 175° C.×30 minutes.

The “arithmetic average roughness (Ra)” is the arithmetic mean roughness measured in accordance with ISO4287:1997, Amd. 1: 2009 (JIS B0601:2013). At the time of obtaining Ra, the standard length Ir (cut-off value: λc) for a roughness curve is set to be 0.8 mm.

The “melt flow rate” means the melt mass flow rate (MFR) as specified in JIS K7210:1999 (ISO1133:1997).

A “unit” is meant for an atomic group derived from a monomer, which is formed by polymerization of the monomer. A unit may be a unit directly formed by the polymerization reaction, or may be a unit having a part of the unit converted to another structure by treating the polymer.

An “acid anhydride group” means a group represented by —C(═O)—O—C(═O)—.

A “carbonyl group-containing group” is a group containing a carbonyl group (—C(═O)—) in its structure.

A “(meth)acrylate” is a general term for an acrylate and a methacrylate. An expression “ to ” showing a numerical range is meant to include the numerical values given before and after the expression as the lower limit value and the upper limit value. Here, in a case where their units are the same, the unit may be identified only for the upper limit value, and may be omitted for the lower limit value.

“%” means “% by mass” unless otherwise specified.

### [Laminated Body]

According to the method for producing a laminated body of the present invention, the following laminated body I is produced, and, as the case requires, the following laminated body II is produced by using the laminated body I.

Laminated body I: A laminated body in which, on one side or both sides of a first substrate, a second substrate is laminated directly, so that its first surface faces the first substrate side.

Laminated body II: A laminated body in which, on the second substrate of the laminate body I, a third substrate is laminated directly.

The first substrate is composed of either one or both of a heat-resistant substrate layer and a metal foil layer.

The second substrate contains a fluorocarbon resin. The second substrate has a first surface of which the wetting tension is from 30 to 60 mN/m and a second surface of which the wetting tension is smaller than (the wet tension of the first surface−2 mN/m).

The second substrate may be laminated on one side of the first substrate, or may be laminated on both sides of the first substrate. From the viewpoint of suppressing warpage of the laminated body, obtaining a double-sided metal-clad laminated board which is excellent in electrical reliability, etc., it is preferred that the second substrate is laminated on both sides of the first substrate.

In a case where the second substrate is laminated on both sides of the first substrate, the respective second substrates may be different or may be the same. From the viewpoint of suppressing warpage of the laminated body, it is preferred that the respective second substrates are the same. Here, the respective second substrates being the same, means that the materials constituting the respective second substrates (the type of the fluororesin, the types of other resins and additives, and the composition such as their contents) and the thickness, are the same.

The third substrate is composed of either one or both of a heat-resistant substrate layer and a metal foil layer.

In a case where the laminated body I is a laminated body in which the second substrate is laminated on both sides of the first substrate, the third substrate may be laminated on one side of the laminated body I, or may be laminated on both sides of the laminated body I.

In a case where the third substrate is laminated on both sides of the laminated body I, the respective third substrates may be the same or different. From the viewpoint of suppressing warpage of the laminated body, it is preferred that the respective third substrates are the same.

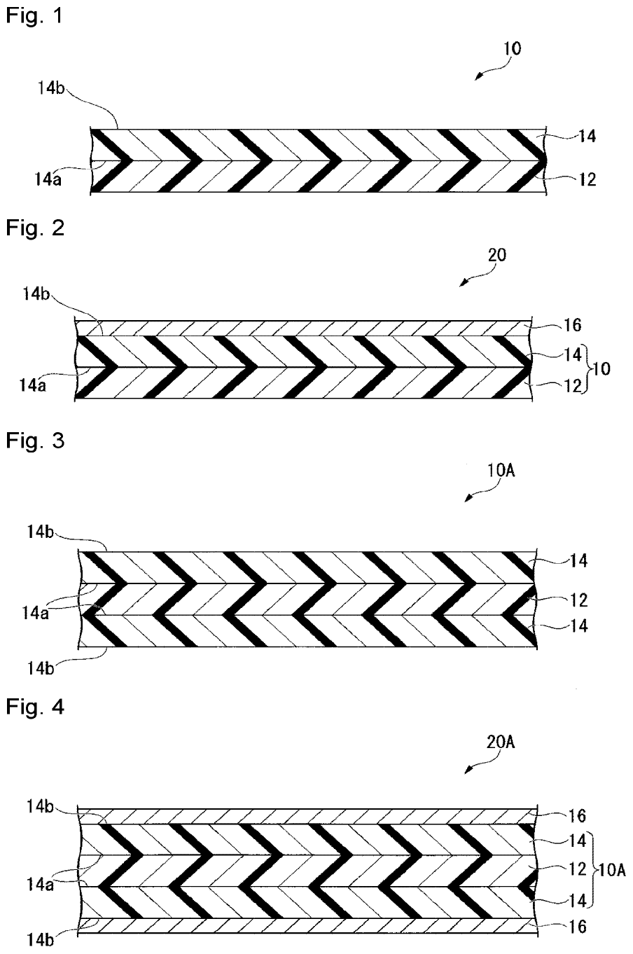

FIG. 1 is a schematic cross-sectional view showing an example of the laminated body I. A laminated body 10 of this embodiment has a heat-resistant substrate layer 12 (first substrate) and a second substrate 14. The second substrate 14 is laminated directly on one side of the heat-resistant substrate layer 12 so that its first surface 14a faces the first substrate side.

FIG. 2 is a schematic cross-sectional view showing an example of the laminated body II. A laminated body 20 of this example is one using the laminated body 10 as the laminated body I, and has the laminated body 10 and a metal foil layer 16 (third substrate). The metal foil layer 16 is laminated directly on the second substrate 14 of the laminated body 10, and is in contact with a second surface 14b of the second substrate 14.

FIG. 3 is a schematic cross-sectional view showing another example of the laminated body I. A laminated body 10A of this embodiment has a heat-resistant substrate layer 12 (first substrate) and two layers of second substrate 14. The two layers of second substrate 14 are, respectively, laminated on both sides of the heat-resistant substrate layer 12, so that the first surface 14a faces the first substrate side.

FIG. 4 is a schematic cross-sectional view showing another example of the laminated body II. A laminated body 20A of this example is one using the laminated body 10A as the laminated body I, and has the laminated body 10A and two layers of metal foil layer 16 (third substrate). The two layers of metal foil layer 16 are, respectively, laminated directly on the two layers of second substrate 14 of the laminated body 10A, and are each in contact with the second surface 14b of the second substrate 14.

However, the constructions of the laminated body I and the laminated body II are not limited to the examples shown in FIGS. 1 to 4, and the first substrate or the third substrate to be combined with the first substrate may be optionally changed. Further, the dimensional ratios of the respective layers in FIGS. 1 to 4 may also be optionally changed.

For example, in the examples shown in FIGS. 1 and 2, the heat-resistant substrate layer 12 of the first substrate may be made to be a substrate composed of a metal foil layer, or a heat-resistant substrate layer and a metal foil layer. In the example shown in FIG. 2, the metal foil layer 16 of the third substrate may be made to be a heat-resistant substrate layer, or a substrate composed of a heat-resistant substrate layer and a metal foil layer.

In a case where the laminated body II is to be used in the production of a flexible printed circuit board, it is preferred to select the first substrate and the third substrate so that at least one of the outermost layers of the laminated body II will be a metal foil layer.

As examples of the laminated structure of the laminated body II in which at least one of the outermost layers will be a metal foil layer, the following laminated structures may be mentioned.

(1) heat-resistant substrate layer/second substrate/metal foil layer

(2) (metal foil layer/heat-resistant substrate layer)/second substrate/metal foil layer

(3) (metal foil layer/heat-resistant substrate layer)/second substrate/heat-resistant substrate layer

(4) (metal foil layer/heat-resistant substrate layer)/second substrate/(heat-resistant substrate layer/metal foil layer)

(5) metal foil layer/second substrate/heat-resistant substrate layer/second substrate/metal foil layer

(6) (metal foil layer/heat-resistant substrate layer)/second substrate/heat-resistant substrate layer/second substrate/metal foil layer

(7) (metal foil layer/heat-resistant substrate layer)/second substrate/heat-resistant substrate layer/second substrate/heat-resistant substrate layer

(8) (metal foil layer/heat-resistant substrate layer)/second substrate/heat-resistant substrate layer/second substrate/(heat-resistant substrate layer/metal foil layer)

Here, in the laminated structure of (1), the “heat-resistant substrate layer/second substrate/metal foil layer” indicates that the heat-resistant substrate layer, the second substrate and the metal foil layer are laminated in this order, and in other laminated structures, the respective layers are similarly laminated.

In the laminated structures of (2) to (4) and (6) to (8), the portion reading (metal foil layer/heat-resistant substrate layer) or (heat-resistant substrate layer/metal foil layer) represents a substrate composed of a heat-resistant substrate layer and a metal foil layer. This substrate is laminated to the second substrate so that the outermost layer on the side opposite to the second substrate be the metal foil layer.

In the laminated structure of (1), either one of the left side (heat-resistant substrate layer side) and the right side (metal foil layer side) of the second substrate may be used as the first surface side. The same applies to the laminated structures of (2) to (4).

The thickness of the laminated body II is not particularly limited, but is usually from 25 to 200 μm. To be used in the production of a flexible printed circuit board, from 25 to 200 μm is preferred, and from 30 to 150 μm is particularly preferred.

The adhesion strength between the layers in the laminated body I (the adhesion strength at the interface between the first substrate and the second substrate) is preferably at least 0.05 N/cm, more preferably at least 0.2 N/cm, further preferably at least 0.3 N/cm. The upper limit is not particularly limited, but is typically at most 1.0 N/cm.

The adhesion strength between the layers in the laminated body II (the lower adhesion strength as between the adhesion strength at the interface between the first substrate and the second substrate, and the adhesion strength at the interface between the second substrate and the third substrate) is preferably at least 9 N/cm, more preferably at least 13 N/cm, further preferably at least 15 N/cm. The adhesion strength between the layers in the laminated body II should better be stronger, and the upper limit is not particularly limited.

The respective adhesion strengths of the laminated bodies I and II will be measured by the methods as described in Examples given later.

### (First Substrate)

The first substrate is composed of either one or both of a heat-resistant substrate layer and a metal foil layer.

### <Heat-Resistant Substrate Layer>

The heat-resistant substrate layer is a layer containing a heat-resistant substrate other than a metal foil.

As the heat-resistant substrate, a heat-resistant resin film, a woven or nonwoven fabric made of inorganic fibers, a woven or nonwoven fabric made of organic fibers, etc. may be mentioned.

As the heat-resistant resin, for example, a polyimide (an aromatic polyimide, etc.), a polyarylate, a polysulfone, a polyallyl sulfone (a polyether sulfone, etc.), an aromatic polyamide, an aromatic polyether amide, a polyphenylene sulfide, a polyaryl ether ketone, a polyamideimide, a liquid crystal polyester, etc. may be mentioned.

As the inorganic fibers, glass fibers, carbon fibers, etc. may be mentioned. As the woven or nonwoven fabric made of inorganic fibers, glass cloth, nonwoven glass fabric, etc. may be mentioned.

As the organic fibers, aramid fibers, polybenzoxazole fibers, polyarylate fibers, etc. may be mentioned. As the woven or nonwoven fabrics made of organic fibers, aramid paper, aramid cloth, polybenzoxazole cloth, polybenzoxazole nonwoven fabric, etc. may be mentioned.

The heat-resistant substrate layer may have a single-layer structure or a multilayer structure.

As an aromatic polyimide film, various commercially available products may be used. For example, Kapton (trade name) EN manufactured by Du Pont-Toray Co., Ltd., of a single-layer structure, may be mentioned. Further, for example, of a multi-layer structure, UPILEX (trade name) VT or UPILEX NVT manufactured by Ube Industries, Ltd., or PIXEO (trade name) BP manufactured by Kaneka Corporation, in which a thermoplastic polyimide layer is formed on both surfaces of an aromatic polyimide film, may be mentioned. As a liquid crystal polyester, VECSTAR (trade name) CT-Z manufactured by Kuraray Co., Ltd. may be mentioned.

Among polyimide films, one having a lower water absorption is preferred, since deterioration in the dielectric properties at the time of moisture absorption is less, and foaming at the time of lamination at a high temperature is little. As such a polyimide, a copolymer of para phenyl diamine as a diamine, and 3,3′,4,4′-biphenyltetracarboxylic acid dianhydride as a dicarboxylic acid, is preferred. Further, an aromatic polyimide film having no thermoplastic polyimide layer is preferred.

The water absorption of the heat-resistant substrate layer is preferably at most 2.0%, more preferably at most 1.5%, further preferably at most 1.3%. The water absorption is a weight change rate after immersion in water at 23° C. for 24 hours as defined in ASTM D570.

Here, the heat resistance is meant that the tensile elastic modulus at the lowest temperature of 260° C. in a solder reflow process is at least 10⁸ Pascal.

The thickness of the heat-resistant substrate layer is usually from 5 to 150 μm, preferably from 7.5 to 100 μm, particularly preferably from 12 to 75 μm.

### <Metal Foil Layer>

The metal foil layer is a layer made of a metal foil. As the metal foil, it is optionally selected according to the application of the laminated body. For example, in a case where the laminated body is to be used for an electronic or electrical equipment, as a material of the metal foil, copper, a copper alloy, stainless steel, its alloy, nickel, a nickel alloy (including 42 alloy), aluminum, an aluminum alloy or the like, may be mentioned. In a usual laminated body to be used for an electronic or electrical equipment, a copper foil such as a rolled copper foil or an electrolytic copper foil is frequently used, and also in the present invention, a copper foil is preferably used.

On the surface of the metal foil, an anticorrosive layer (e.g. an oxide covering film of chromate, etc.) or a heat-resistant layer may be formed. On the surface of the metal foil, surface treatment for increasing the adhesion strength to the second substrate (e.g. coupling agent treatment, etc.) may be applied.

The thickness of the metal foil layer may be suitably selected to be such a thickness that sufficient functions can be exhibited depending on the application of the laminated body. For example, in the case of using the laminated body for an electronic or electrical equipment, it may be in a range of from 5 to 75 μm.

The surface roughness of the metal foil layer is preferably low in a range where the adhesive strength can be maintained. In particular, Rzⱼᵢₛ is preferably from 0.1 to 2.0 μm. When Rzⱼᵢₛ is at least 0.1 μm, adhesion will be excellent, and when it is at most 2.0 μm, electrical properties will be excellent.

The surface roughness Rzⱼᵢₛ here, is a ten-point average roughness as defined by JIS

B0601:2013, Annex JA.

In a case where the metal foil is a copper foil, it may be an electrolytic copper foil to be formed by electrolysis, or may be a rolled copper foil obtainable by rolling a copper ingot.

In a case where the first substrate is composed of a heat-resistant substrate layer and a metal foil layer, the heat-resistant substrate material layer and the metal foil layer may be laminated directly, or may be laminated through an adhesive layer. The material for the adhesive layer may, for example, be a thermoplastic polyimide, an epoxy resin, etc.

(Second Substrate)

The second substrate contains a fluororesin, and in the laminated body I or II, the second substrate constitutes a layer containing a fluororesin (a fluororesin layer).

The second substrate may contain, in addition to the fluororesin, an additive, a resin other than the fluororesin, etc.

The content of the fluororesin in the second substrate is preferably at least 50 mass %, more preferably at least 80 mass %, to the total mass (100 mass %) of the second substrate. The upper limit for the content of the fluororesin is not particularly limited and may be 100 mass %.

The wetting tension of the first surface of the second substrate is from 30 to 60 mN/m, preferably from 30 to 50 mN/m.

The first surface of which the wetting tension is at least the above lower limit value, usually has adhesive functional groups (such as carbonyl group-containing groups, hydroxy groups, amino groups, etc.) formed by surface treatment such as corona discharge treatment, and the more the amount of the adhesive functional groups, the higher the wetting tension tends to be. When the wetting tension of the first surface is at least the above lower limit value, even if the temperature at the time of laminating the first substrate and the second substrate is low, a sufficient reaction occurs between the adhesive functional groups of the first surface and the first substrate, whereby a sufficient adhesion force can be obtained. When the wetting tension of the first surface is at most the above upper limit value, contaminants to be formed by the surface treatment will be less, and adhesion inhibition by contaminants will be less likely to occur, whereby a sufficient adhesion force can be obtained.

The wetting tension of the second surface of the second substrate is smaller by at least 2 mN/m than the wetting tension of the first surface, preferably smaller by at least 4 mN/m than the wetting tension of the first surface, particularly preferably smaller by at least 6 mN/m than the wetting tension of the first surface. Therefore, the difference in wetting tension between the first surface and the second surface (the wetting tension of the first surface−the wetting tension of the second surface) is at least 2 mN/m, preferably at least 4 mN/m, particularly prefer at least 6 mN/m. Further, the wetting tension of the second surface of the second substrate is preferably from 22.6 to 30.0 mN/m, more preferably from 22.6 to 27.3 mN/m.

At the time of laminating the first substrate and the second substrate, a pressure is applied from both sides of the first substrate and the second substrate by a laminating means such as a pair of rolls. At that time, the first surface of the second substrate is in contact with the first substrate, and the second surface is in contact with the laminating means.

When the difference in the wetting tension is at least the above lower limit value, at the time of laminating the first substrate and the second substrate, a sufficient difference will be formed between the adhesion force to the first substrate and the adhesion force to the laminating means, of the second substrate. Namely, the adhesion force to the laminating means will be sufficiently lower than the adhesion force to the first substrate. Therefore, at the time of removing the laminated body I from the laminating means after pressing, it is possible to prevent the second substrate from being peeled from the first substrate by the laminating means, and it is possible to obtain a laminated body I free from delamination.

The above difference in the wetting tension is preferably larger, and its upper limit, i.e. the lower limit for the wetting tension of the second surface is not particularly limited.

Here, the wetting tensions of the first surface and the second surface of the second substrate, are, respectively, values before the second substrate is laminated to the first substrate, and when made into the laminated body I.

At the time of obtaining the laminated body II, since heating is conducted at a temperature T₂ of at least the melting point of the fluororesin, the wetting tensions of the first surface and the second surface will be changed. However, at a temperature T₁ of from 0 to 100° C. at the time of obtaining the laminated body I, in general, the wetting tensions prior to lamination will be maintained.

If functional groups are formed on the outermost surface (the first surface or the second surface) by surface treatment, the elemental composition of the outermost surface changes as compared to before the surface treatment.

As elements to be formed on the outermost surface by the surface treatment, oxygen, nitrogen, etc. may be mentioned.

The presence of oxygen at the first surface (after surface treatment) is preferably from 0.1 to 10 mol %, more preferably from 0.5 to 8 mol %. In this range, the wetting tension of the first surface is likely to fall within the desired range.

The presence of nitrogen at the first surface is preferably from 0.01 to 5 mol %, more preferably from 0.02 to 4 mol %. In this range, the wetting tension of the first surface is likely to fall within the desired range. Here, the presence of an element is a value measured by an X-ray photoelectron spectroscopy.

The arithmetic average roughness Ra of each of the first surface and the second surface of the second substrate is preferably from 0.001 to 3 μm, more preferably from 0.005 to 2 μm. When Ra is at least the above lower limit value, it is less likely to stick to the free roll during the transport by roll-to-roll. When Ra is at most the above upper limit value, adhesion will be more excellent when laminated with another substrate.

The thermal expansion rate of the second substrate is preferably from 0.0 to −2.0%, more preferably from 0.0 to −1.0%. When the thermal expansion rate is at most 0.0%, it tends to be easy to prevent wrinkles due to thermal expansion of the second substrate. When the thermal expansion rate is at least −2.0%, the dimension in the width direction after lamination will be stabilized.

The thermal expansion rate can be adjusted depending on conditions at the time of forming the second substrate film.

The thickness of the second substrate is usually from 1 to 1,000 μm, preferably from 5 to 500 μm, and from the viewpoint of chemical resistance and flame resistance, it is preferably at least 10 μm. In particular, from 10 to 500 μm is preferred, from 10 to 300 μm is more preferred, from 10 to 200 μm is particularly preferred, and from 12 to 50 μm is further preferred.

The second substrate is preferably made of a film containing a fluororesin (hereinafter referred to also as a fluororesin film), from the viewpoint of the productivity of the laminated body, the handling efficiency of the laminated body, etc. The second substrate may be a substrate of a single layer structure consisting of one fluororesin film, or may be a substrate of a multilayer structure consisting of a plurality of fluororesin films.

A fluororesin film can be produced by molding a molding material containing a fluororesin by a known molding method (an extrusion molding method, an inflation molding method, etc.). The molding material may contain an additive, a resin other than the fluororesin, etc.

As the fluororesin in the fluororesin film, a melt-moldable fluororesin is preferred. That is, as the fluororesin film, a film obtained by molding a molding material containing a melt-moldable fluororesin into a film, is preferred.

Control of the wetting tension of the second substrate is preferably carried out by surface treatment. That is, the second substrate may be produced by, for example, (α) a method of surface-treating only the first surface of a fluororesin film, (β) a method of surface-treating the first surface and the second surface of a fluororesin film, respectively, under different conditions, (γ) a method of surface-treating also the second surface by passing through from the first surface of the fluororesin film.

In each of the methods (α), (β) and (γ), the surface treatment is conducted so that the wetting tension of the first surface after the surface treatment, and the difference in the wetting tension between the first surface and the second surface (the wetting tension of the first surface−the wetting tension of the second surface) will, respectively, satisfy the above-mentioned values.

The wetting tension may be changed by e.g. surface treatment conditions, the fluorine content of the fluororesin contained in the second substrate, etc. For example, in a case where the surface treatment is discharge treatment such as corona discharge treatment, the larger the discharge amount, the higher the wetting tension tends to be. The fluorine content of the fluororesin is preferably from 70 to 78 mass %, and, in this range, even with the same discharge amount, the smaller the fluorine content of the fluororesin, the higher the wetting tension tends to be.

The surface treatment of the fluororesin film may be a treatment for increasing the wetting tension of the treated surface, and, as an example, a discharge treatment such as corona discharge treatment, plasma treatment (atmospheric pressure plasma discharge treatment, vacuum plasma discharge treatment, etc. but excluding corona discharge treatment), etc., plasma graft polymerization treatment, electron beam irradiation, light irradiation treatment such as excimer UV light irradiation, etc., ITRO treatment using a flame, wet etching treatment using metal sodium, etc. may be mentioned. When such surface treatment is applied, adhesive functional groups will be formed on the surface of the fluororesin film, whereby the wetting tension will be increased.

As the surface treatment, from the viewpoint of economy and from such a viewpoint that it will be easy to obtain the desired wetting tension, a discharge treatment is preferred, and corona discharge treatment, atmospheric pressure plasma treatment or vacuum plasma treatment is particularly preferred. In the discharge treatment, by making the environment during the discharge to be under the presence of oxygen, oxygen radicals and ozone will be formed, whereby it is possible to efficiently introduce carbonyl group-containing groups to the film surface. The reason for this is as follows.

By the action of high-energy electrons (about from 1 to 10 eV) generated by the discharge, the main chain or side chain in the binding of the surface material (an oxide layer or an oil film on the surface in the case of metal) will be dissociated to become radicals. Further, molecules of the ambient gas such as the air, moisture, etc. will also be dissociated to become radicals. By the recombination reaction of such two types of radicals to each other, hydrophilic functional groups such as hydroxy groups, carbonyl groups, carboxy groups, etc. will be formed on the surface of the treated object. As a result, the free energy at the surface of the treated object be will be increased, whereby adhesion or bonding to another surface will be easy.

Particularly, by vacuum plasma treatment, in the later-described second step, it is possible to lower the laminating temperature, such being more preferred from the viewpoint of dimensional stability.

For corona discharge treatment, a known treatment system (corona discharge treatment apparatus) may be applied. The treatment system is typically provided with a corona discharge treatment section in which a pair of electrodes are arranged so that one of the electrodes is an electrode that is not covered, and the other electrode is a roll electrode covered with a dielectric (dielectric roll). Corona discharge is formed by causing dielectric breakdown of air by applying a high frequency high voltage between the electrodes. The film transported by a roll will pass through the discharge, whereby the film surface will be treated. The film will pass near one of the electrodes, or near the center between the electrodes. In the case where the film will pass near the center between the electrodes, both sides of the film will be treated. On the other hand, in the case where the film is transported along the dielectric roll, the surface on the electrode side not covered with the dielectric will be treated. The construction of such a system has been known from relatively long ago, and it is applied to surface treatment of various resin films. Here, the inter-electrode distance is required to be at most a few cm, whereby although treatment of a three-dimensional object or big object is difficult, with an object having a shape like a film, treatment in a relatively large area is possible.

As the shape of electrodes, wire-like electrodes, segment electrodes, etc. may be mentioned. As the shape of segment electrodes, needle electrodes, groove-type electrodes, blade-type electrodes, hemispherical electrodes, etc. may be mentioned. From the viewpoint of uniformity of the discharge, segment electrodes are preferred, and as the shape, blade-type electrodes are preferred.

As the material for the dielectric, silicone rubber, glass, ceramics, etc. may be mentioned. Silicone rubber is preferred from the viewpoint of uniformity of the discharge.

In corona discharge treatment to the first surface of a fluororesin film, the discharge amount is preferably from 10 to 200 W·min/m², more preferably from 20 to 150 W·min/m². When the discharge amount is within the above range, the wetting tension of the first surface after the treatment tends to be within the above-mentioned range.

Corona discharge treatment on the first surface may be treatment for once or may be treatment for a plurality of times. The same applies in a case where corona discharge treatment is carried out on the second surface.

The gas in the corona discharge treatment section may be the atmospheric air, but a gas may be added. As the gas to be added, for example, nitrogen, argon, oxygen, helium, a polymerizable gas (such as ethylene), etc. may be mentioned.

The absolute humidity in the corona discharge treatment section is preferably from 10 to 30 g/m³. When the absolute humidity is at least 10 g/m³, discharge can be conducted stably without formation of sparks. When it is at most 30 g/m³, the change in the discharge amount is small, and it is easy to obtain a uniform wetting tension.

In vacuum plasma treatment, treatment by glow discharge is conducted in a reduced pressure container. Since it is plasma treatment using glow discharge, the voltage to be applied, can be made to be lower than the voltage used in the corona discharge of the conventional construction, and it is possible to reduce the power consumption. With the treatment pressure being preferably in a range of from 0.1 to 1,330 Pa, more preferably from 1 Pa to 266 Pa, glow discharge treatment for self-sustained discharge, so-called low-temperature plasma treatment, is preferred from the viewpoint of treatment efficiency.

At that time, treatment in vacuum where selection of treatment gas is wide, is preferred. As the treatment gas, although not particularly limited, He, Ne, Ar, nitrogen, oxygen, carbon dioxide gas, air, water vapor, etc. may be used alone or in a mixed state. Among them, Ar or carbon dioxide gas is preferred from the viewpoint of the discharge starting efficiency. Further, a combination of Ar, hydrogen and nitrogen is also preferred, since it is possible to impart highly reactive functional groups to the substrate.

It is possible to carry out stable glow discharge by applying an electric power of 10 W to 100 KW, for example, at a high frequency of from 10 KHz to 2 GHz, between discharge electrodes under the above-mentioned gas pressure. As the discharge frequency band, it is possible to use, other than the high frequency, low frequency, a microwave, DC, etc. The vacuum plasma generator is preferably an internal electrode type, but in some cases, it may be an external electrode type, and may also be either capacitive coupling such as a coil furnace, or inductive coupling.

The shape of the electrodes may be various, such as plate-shaped, ring-shaped, rod-shaped, cylindrical, etc., and may further be a shape in which a metal inner wall of the treatment apparatus is grounded as one of the electrodes. In order to maintain stable plasma conditions by applying a voltage of at least 1,000 volts between the electrodes, it is preferred to apply an insulating covering having considerable withstand voltage to the input electrode. When it is a metal bare electrode of copper, iron, aluminum or the like, it tends to bring about arc discharge, and therefore, it is preferred to apply enamel coating, glass coating, ceramic coating or the like to the electrode surface.

In the case of carrying out vacuum plasma treatment to a fluororesin film, it is preferred to adjust the treatment power (output) to be within a range of from 5 to 400 W·min/m². This makes it possible to obtain the above-mentioned range of the wetting tension at the surface of the fluororesin film.

In the atmospheric pressure plasma discharge treatment, by discharging in an inert gas (argon gas, nitrogen gas, helium gas, etc.) under from 0.8 to 1.2 atm., glow discharge is generated. In the inert gas, a very small amount of an active gas (oxygen gas, hydrogen gas, carbon dioxide gas, ethylene, tetrafluoroethylene, etc.) may be mixed. As the gas, from such a viewpoint that the wetting tension at the surface of the fluororesin layer is likely to be within the above range, a gas having hydrogen gas mixed to nitrogen gas, is preferred.

The voltage in atmospheric pressure plasma discharge treatment is usually from 1 to 10 kV. The frequency of the power source is usually from 1 to 20 kHz. The treatment time is usually from 0.1 second to 10 minutes.

The discharge power density in the atmospheric pressure plasma discharge treatment is preferably from 5 to 400 W·min/m². When the discharge power density is within the above range, the wetting tension at the surface of the fluororesin layer is likely to be within the above-mentioned range.

Further, in a case where the first substrate and the third substrate are heat-resistant resin films, the same surface treatment as for the fluororesin film may be carried out. As the surface treatment, corona discharge treatment, atmospheric pressure plasma treatment or vacuum plasma treatment is preferred, and atmospheric pressure plasma treatment or vacuum plasma treatment is more preferred. By carrying out such treatment to the heat-resistant resin film, the adhesion strength in the later-described second step will be improved.

The water contact angle at the surface of the heat-resistant resin film is preferably from 5° to 60°, more preferably from 10° to 50°, further preferably from 10° to 30°. When the water contact angle is within the above range, adhesion between the fluororesin layer and the heat-resistant resin layer after lamination will be further excellent.

For example, in a case where the heat-resistant resin film is an aromatic polyimide film, the water contact angle before the surface treatment at the surface of the aromatic polyimide film is preferably from 70° to 80°. The water contact angle is a value measured by the sessile drop method as described in JIS R6769:1999.

<Fluororesin>

As the fluororesin, from such viewpoint that it will be easy to produce a film, a melt-moldable fluororesin is preferred. As such a fluororesin, a known one may be used.

As the melt-moldable fluororesin, preferred is a fluororesin such that at a temperature higher by at least 20° C. than the melting point of the fluororesin under a condition of a load of 49 N, there is a temperature at which the melt flow rate becomes to be from 0.1 to 1,000 g/10 min (preferably from 0.5 to 100 g/10 min, more preferably from 1 to 30 g/10 min, further preferably from 5 to 20 g/10 min). When the melt flow rate is at least the lower limit value in the above range, moldability of the fluororesin will be excellent, and the fluororesin film will be excellent in the surface smoothness and appearance. When the melt flow rate is at most the upper limit value in the above range, mechanical strength of the fluororesin film will be excellent.

The melting point of the fluororesin is preferably from 100 to 325° C., more preferably from 250 to 320° C., further preferably from 280 to 315° C. When the melting point of the fluororesin is at least the lower limit value in the above range, the heat resistance of the obtainable laminated body will be more excellent. When the melting point of the fluororesin is at most the upper limit value in the above range, it is possible to use a general-purpose molding apparatus at the time of producing the laminated body. Hereinafter, unless otherwise specified, the fluororesin means a fluororesin having the above-mentioned melting point.

The fluorine content in the fluororesin is preferably from 70 to 80 mass %, particularly preferably from 70 to 78 mass %. The fluorine content is the proportion of the total mass of fluorine atoms to the total mass of the fluororesin. When the fluorine content is at least the above lower limit value, the heat resistance will be more excellent, and when it is at most the above upper limit value, the moldability will be more excellent. The fluorine content is measured by ¹⁹F-NMR.

The fluororesin may be a fluororesin having no adhesive functional group, or may be a fluororesin having adhesive functional groups. From such a viewpoint that the adhesive strength between the second substrate and the first substrate or the third substrate will be more excellent when formed into a laminated body II, it is preferably a fluororesin having adhesive functional groups.

The fluororesin having no adhesive functional group may be a tetrafluoroethylene/perfluoro(alkyl vinyl ether) copolymer (PFA), a tetrafluoroethylene/hexafluoropropylene copolymer (FEP), an ethylene/tetrafluoroethylene copolymer (ETFE), polyvinylidene fluoride (PVDF), polychlorotrifluoroethylene (PCTFE), an ethylene/chlorotrifluoroethylene copolymer (ECTFE), etc.

As the fluororesin having no adhesive functional group, from such a viewpoint that it is possible to efficiently introduce adhesive functional groups to the surface of a fluororesin film by surface treatment such as corona discharge treatment, a fluororesin having hydrogen atoms bonded to carbon atoms, such as ETFE, PVDF, etc. is preferred

The fluororesin having adhesive functional groups may be the above fluororesin having a unit having an adhesive functional group, or a terminal group having an adhesive functional group. Specifically, PFA having adhesive functional groups, FEP having adhesive functional groups, ETFE having adhesive functional groups, etc. may be mentioned.

The adhesive functional groups in the fluororesin having adhesive functional groups, are preferably at least one type of functional group selected from the group consisting of a carbonyl group-containing group, a hydroxy group, an epoxy group, an amide group, an amino group and an isocyanate group. The adhesive functional groups in the fluororesin may be of one type, or may be of two or more types.

The adhesive functional groups in the fluororesin are preferably carbonyl group-containing groups, from the viewpoint of the adhesive property at the interface. The carbonyl group-containing group may, for example, be a group having a carbonyl group between carbon atoms of a hydrocarbon group, a carbonate group, a carboxy group, a haloformyl group, an alkoxycarbonyl group, an acid anhydride group, etc.

The hydrocarbon group in the group having a carbonyl group between carbon atoms of a hydrocarbon group, may, for example, be a C₂₋₈ alkylene group. The number of carbon atoms in the alkylene group is the number of carbon atoms that does not include carbon atoms of the carbonyl group. The alkylene group may be linear, or may be branched.

The haloformyl group is represented by —C(═O)—X (wherein X is a halogen atom). The halogen atom in the haloformyl group may be a fluorine atom, a chlorine atom, etc., and a fluorine atom is preferred. That is, as the haloformyl group, a fluoroformyl group (referred to also as a carbonyl fluoride group) is preferred.

The alkoxy group in the alkoxycarbonyl group may be linear, or may be branched; a C₁₋₈ alkoxy group is preferred, and a methoxy group or an ethoxy group is particularly preferred.

As the carbonyl group-containing group, an acid anhydride group or a carboxy group is preferred.

The content of adhesive functional groups in the fluororesin is, to 1×10⁶ carbon atoms in the main chain of the fluororesin, preferably from 10 to 60,000 pieces, more preferably from 100 to 50,000 pieces, further preferably from 100 to 10,000 pieces, particularly preferably from 300 to 5,000 pieces. When the content is at least the lower limit value in the above range, the adhesion at the interface will be further excellent. When the content is at most the upper limit value in the above range, the adhesion strength between the second substrate and the first substrate or the third substrate will be more excellent when formed into a laminated body II.

The content of the adhesive functional groups can be measured by a method such as nuclear magnetic resonance (NMR) analysis, infrared absorption spectrum analysis, etc. For example, as described in JP-A-2007-314720, by using a method such as infrared absorption spectrum analysis, etc., the proportion (mol %) of units having adhesive functional groups in all units constituting the fluororesin is obtainable, and from the proportion, the content of the adhesive functional groups can be calculated.

From the viewpoint of adhesion at the interface, the adhesive functional groups are preferably present as either one or both of terminal groups of the main chain and pendant groups of the main chain in the fluororesin.

Such a fluororesin may be produced by a method of e.g. copolymerizing a monomer having an adhesive functional group at the time of the polymerization of the monomer, or polymerizing a monomer by using a chain transfer agent or polymerization initiator which brings about an adhesive functional group. These methods may be used in combination. In particular, by co-polymerizing a monomer having an adhesive functional group, it is preferred to obtain a fluororesin wherein the adhesive functional groups are present as at least pendant groups of the main chain.

As the monomer having an adhesive functional group, a monomer having a carbonyl group-containing group, a hydroxy group, an epoxy group, an amide group, an amino group or an isocyanate group, is preferred, and a monomer having an acid anhydride group or a carboxy group is particularly preferred. Specifically, a monomer having a carboxy group of e.g. maleic acid, itaconic acid, citraconic acid, undecylenic acid, etc., a monomer having an acid anhydride group of e.g. itaconic anhydride (IAN), citraconic anhydride (CAH), 5-norbornene-2,3-dicarboxylic acid anhydride (NAH), maleic anhydride, etc., a hydroxyalkyl vinyl ether, an epoxy alkyl vinyl ether, etc. may be mentioned.

As the chain transfer agent which brings about an adhesive functional group, a chain transfer agent having a carboxy group, an ester bond, a hydroxy group, etc. is preferred. Specifically, acetic acid, acetic anhydride, methyl acetate, ethylene glycol, propylene glycol, etc. may be mentioned.

As the polymerization initiator which brings about an adhesive functional group, a peroxide type polymerization initiator such as a peroxy carbonate, a diacyl peroxide, a peroxy ester, etc. is preferred. Specifically, di-n-propyl peroxydicarbonate, diisopropyl peroxydicarbonate, tert-butylperoxy isopropyl carbonate, bis(4-tert-butylcyclohexyl) peroxydicarbonate, di-2-ethylhexyl peroxydicarbonate, etc. may be mentioned.

As the fluororesin wherein adhesive functional groups are present as at least pendant groups of the main chain, from the viewpoint of further excellent adhesion, the following fluorinated polymer A is particularly preferred.

Fluorinated polymer A: A fluorinated polymer having units derived from tetrafluoroethylene (TFE), units derived from a cyclic hydrocarbon monomer having an acid anhydride group (hereinafter referred to also as an acid anhydride-type monomer) and units derived from a fluorinated monomer (but excluding TFE).

Hereinafter, units derived from TFE will be referred to also as “TFE units”, units derived from an acid anhydride-type monomer will be referred to also as “units (2)”, and units derived from the above fluorinated monomer will be referred to also as “units (3)”.

As the acid anhydride-type monomer, IAH, CAH, NAH, maleic anhydride, etc. may be mentioned, and one type among them may be used alone, or two or more types may be used in combination.

As the acid anhydride-type monomer, at least one type selected from the group consisting of IAH, CAH and NAH is preferred. When any one of IAH, CAH and NAH is used, it is possible to easily produce a fluorinated polymer A having acid anhydride groups without using a special polymerization method required in the case of using maleic anhydride (see JP-A-11-193312).

As the acid anhydride-type monomer, IAH or NAH is particularly preferred from such a viewpoint that the adhesion at the interface will be further excellent.

In the fluorinated polymer A, there may be a case where some of acid anhydride groups in units (2) undergo hydrolysis and, as a result, units of a dicarboxylic acid (itaconic acid, citraconic acid, 5-norbornene-2,3-dicarboxylic acid, maleic acid, etc.) corresponding to the acid anhydride-type monomer will be contained. In the case where the units of such a dicarboxylic acid are contained, the content of the units shall be included in the content of units (2).

The fluorinated monomer to constitute units (3) is preferably a fluorinated monomer having a polymerizable carbon-carbon double bond. For example, a fluoroolefin (chlorotrifluoroethylene, vinyl fluoride, vinylidene fluoride, trifluoroethylene, hexafluoropropylene (HFP), hexafluoroisobutylene, etc., but excluding TFE), CF₂═CFOR^{f1} (where R^{f1} is a C₁₋₁₀ perfluoroalkyl group, or a group containing an oxygen atom between carbon atoms of a C₂₋₁₀ perfluoroalkyl group) (hereinafter referred to also as PAVE), CF₂═CFOR^{f2}SO₂X¹ (where R^{f2} is a C₁₋₁₀ perfluoroalkyl group, or a group containing an oxygen atom between carbon atoms of a C₂₋₁₀ perfluoroalkyl group, and X¹ is a halogen atom or a hydroxy group), CF₂═CFOR^{f3}CO₂X² (where R^{f3} is a C₁₋₁₀ perfluoroalkyl group, or a group containing an oxygen atom between carbon atoms of a C₂₋₁₀ perfluoroalkyl group, and X² is a hydrogen atom or a C₁₋₃ alkyl group), CF₂═CF(CF₂)ₚ OCF═CF₂ (where p is 1 or 2), CH₂═CX³(CF₂)_{q}X⁴ (where X³ is a hydrogen atom or a fluorine atom, q is an integer of from 2 to 10, and X⁴ is a hydrogen atom or a fluorine atom) (hereinafter referred to also as FAE), a fluorinated monomer having a ring structure (perfluoro(2,2-dimethyl-1,3-dioxole), 2,2,4-trifluoro-5-trifluoromethoxy-1,3-dioxole, perfluoro(2-methylene-4-methyl-1,3-dioxolane), etc.), etc. may be mentioned.

As the fluorinated monomer, from the viewpoint of the moldability of the fluorinated polymer A, excellent flex resistance of the polymer layer, etc., at least one member selected from the group consisting of HFP, PAVE and FAE is preferred.

PAVE may be CF₂═CFOCF₂CF₃, CF₂═CFOCF₂CF₂CF₃, CF₂═CFOCF₂CF₂CF₂CF₃, CF₂═CFO(CF₂)₈F, etc., and CF₂═CFOCF₂CF₂CF₃ (PPVE) is preferred.

FAE may be CH₂═CF(CF₂)₂F, CH₂═CF(CF₂)₃F, CH₂═CF(CF₂)₄F, CH₂═CF(CF₂)₅F, CH₂═CF(CF₂)₈F, CH₂═CF(CF₂)₂H, CH₂═CF(CF₂)₃H, CH₂═CF(CF₂)₄H, CH₂═CF(CF₂)₅H, CH₂═CF(CF₂)₈H, CH₂═CH(CF₂)₂F, CH₂═CH(CF₂)₃F, CH₂═CH(CF₂)₄F, CH₂═CH(CF₂)₅F, CH₂═CH(CF₂)₆F, CH₂═CH(CF₂)₈F, CH₂═CH(CF₂)₂H, CH₂═CH(CF₂)₃H, CH₂═CH(CF₂)₄H, CH₂═CH(CF₂)₅H, CH₂═CH(CF₂)₈H,etc.

As FAE, CH₂═CH(CF₂)_{q1}X⁴ (where q1 is from 2 to 6, preferably from 2 to 4) is preferred; CH₂═CH(CF₂)₂F, CH₂═CH(CF₂)₃F, CH₂═CH(CF₂)₄F, CH₂═CF(CF₂)₃H or CH₂═CF(CF₂)₄H is more preferred; and, CH₂═CH(CF₂)₄F (PFBE) or CH₂═CH(CF₂)₂F (PFEE) is particularly preferred.

The fluoropolymer A may further contain, in addition to TFE units and units (2) and (3), units derived from a non-fluorinated monomer (but excluding an acid anhydride type monomer).

As the non-fluorinated monomer, a non-fluorinated compound having one polymerizable carbon-carbon double bond is preferred, and, for example, an olefin (ethylene, propylene, 1-butene, etc.), a vinyl ester (vinyl acetate, etc.), etc. may be mentioned. As the non-fluorinated monomer, one type may be used alone, or two or more types may be used in combination.

Preferred examples of the fluorinated polymer A may be a TFE/NAH/PPVE copolymer, a TFE/IAH/PPVE copolymer, a TFE/CAH/PPVE copolymer, a TFE/IAH/HFP copolymer, a TFE/CAH/HFP copolymer, a TFE/IAH/PFBE/ethylene copolymer, a TFE/CAH/PFBE/ethylene copolymer, a TFE/IAH/PFEE/ethylene copolymer, a TFE/CAH/PFEE/ethylene copolymer, a TFE/IAH/HFP/PFBE/ethylene copolymer, etc. Among them, a TFE/NAH/PPVE copolymer is preferred, since the heat resistance is good.

Here, a “TFE/NAH/PPVE copolymer” is meant for a copolymer having TFE units, NAH units and PPVE units, and the same applies to other copolymers.

In a case where the fluorinated polymer A is composed of TFE units, units (2) and units (3), the content of TFE units is preferably from 50 to 99.89 mol %, more preferably from 50 to 99.4 mol %, further preferably from 50 to 98.9 mol %, to the total 100 mol % of TFE units, units (2) and units (3), The content of units (2) is preferably from 0.01 to 5 mol %, more preferably from 0.1 to 3 mol %, further preferably from 0.1 to 2 mol %. The content of units (3) is preferably from 0.1 to 49.99 mol %, more preferably from 0.5 to 49.9 mol %, further preferably from 1 to 49.9 mol %.

When the proportions of the respective units are within the above ranges, the heat resistance, chemical resistance and elastic modulus at a high temperature, of the second substrate, will be more excellent. When the proportion of units (2) is within the above range, the amount of acid anhydride groups in the fluorinated polymer A will be proper and the adhesion will be more excellent. When the proportion of units (3) is within the above range, moldability of the fluorinated polymer A will be excellent, and bending resistance of the laminated body will be more excellent.

The proportions of the respective units can be calculated by the melt NMR analysis, fluorine content analysis and infrared absorption spectrum analysis, of the fluorinated polymer.

In a case where the fluorinated polymer A comprises TFE units, units (2), units (3) and units derived from a non-fluorinated monomer, wherein the units derived from the non-fluorinated monomer are units derived from ethylene (hereinafter referred to also as E units), preferred proportions of the respective units are as follows.

To the total 100 mol % of TFE units, units (2), units (3) and E units, the content of TFE units is preferably from 25 to 80 mol %, more preferably from 40 to 65 mol %, further preferably from 45 to 63 mol %. The content of units (2) is preferably from 0.01 to 5 mol %, more preferably from 0.03 to 3 mol %, further preferably from 0.05 to 1 mol %. The content of units (3) is preferably from 0.2 to 20 mol %, more preferably from 0.5 to 15 mol %, further preferably from 1 to 12 mol %. The content of E units is preferably from 20 to 75 mol %, more preferably from 35 to 50 mol %, further preferably from 37 to 55 mol %.

When the contents of the respective units are within the above ranges, chemical resistance, etc. will be more excellent. When the proportion of units (2) is within the above range, the amount of acid anhydride groups in the fluorinated polymer A will be proper, and adhesion will be more excellent. When the proportion of units (3) is within the above range, moldability of the fluorinated polymer A will be excellent, and bending resistance, etc. of the laminated body will be more excellent.

The fluorinated polymer A can be prepared by a conventional method. For example, it is possible to produce the fluorinated polymer A by polymerizing at least TFE, the acid anhydride-type monomer and the fluorinated monomer. At the time of the polymerization of the monomers, it is preferred to use a radical polymerization initiator.

As the polymerization method, a bulk polymerization method, a solution polymerization method using an organic solvent (a fluorinated hydrocarbon, a chlorinated hydrocarbon, a fluorinated chlorinated hydrocarbon, an alcohol, a hydrocarbon, etc.), a suspension polymerization using an aqueous medium and, if necessary, an appropriate organic solvent, or an emulsion polymerization method using an aqueous medium and an emulsifier, may be mentioned, and a solution polymerization method is preferred.

At the time of producing the fluorinated polymer A, the concentration in the polymerization of the acid anhydride-type monomer is preferably from 0.01 to 5 mol %, more preferably from 0.1 to 3 mol %, further preferably from 0.1 to 2 mol %, to all monomers. When the concentration of said monomer is within the above range, the polymerization rate becomes to be proper. If the concentration of said monomer is too high, the polymerization rate tends to decrease.

As the acid anhydride-type monomer is consumed in the polymerization, it is preferred to maintain the concentration of said monomer within the range, by continuously or intermittently supplying the consumed amount to the polymerization reactor.

(Third Substrate)

The third substrate is composed of either one or both of a heat-resistant substrate layer and a metal foil layer. The heat-resistant substrate layer and the metal foil layer may, respectively, be the same ones as mentioned in the first substrate.

In a case where the third substrate is composed of a heat-resistant substrate layer and a metal foil layer, the heat-resistant substrate layer and the metal foil layer may be laminated directly, or may be laminated via an adhesive layer. As the adhesive layer, the same one as mentioned in the first substrate may be mentioned. The first substrate and the third substrate may be the same or may be different.

### [Method for Producing Laminated Body]

The method for producing a laminated body of the present invention comprises the following first step, and, as the case requires, the following second step.

First step: A step of disposing the second substrate on one side or both sides of the first substrate, so that the first surface faces the first substrate side, and while transporting the first substrate and the second substrate, laminating them by pressing them in the thickness direction (lamination direction) at a temperature T₁ of from 0 to 100° C., to obtain a laminated body I in which the first substrate and the second substrate are directly laminated.

Second step: A step of disposing the third substrate on the second substrate of the laminated body I, and while transporting the laminated body I and the third substrate, laminating them by pressing them in the thickness direction (lamination direction) at a temperature T₂ of at least the melting point of the fluororesin contained in the second substrate, to obtain a laminated body II in which the laminated body I and the third substrate are directly laminated.

### (First Step)

The first step is preferably carried out continuously by a laminating apparatus comprising at least one pair of laminating means.

The laminating means are meant for means to press-bond a plurality of members by pressing them in the lamination direction. The laminating means may, as the case requires, have a heating mechanism. At least one pair of laminating means may be at least one pair of rolls (metal rolls, etc.), at least one pair of belts (metal belts, etc.), etc.

The laminating apparatus may, for example, be a roll laminating apparatus having at least one pair of rolls, a double belt press apparatus having at least one pair of belts, etc.

Here, the double belt press apparatus is meant for an apparatus for forming a laminated body by continuously feeding a plurality of sheet materials between endless belts arranged in an upper and lower pair, and heat-press bonding the sheet materials via the endless belts by a heat-press bonding apparatus. For said heat-press bonding apparatus, there are a few systems including a system of surface pressing by using a liquid pressure plate (referred to as a liquid pressure system), a roll pressure system conducted by drums to rotate the endless belts and/or rollers installed between the drums, etc.

The specific construction of the roll laminating apparatus is not particularly limited. Typically, an apparatus having at least one pair of rolls capable of press bonding a plurality of members while heating them, is employed.

As the heating system in the laminating means, it is possible to employ a known system capable of heating at a predetermined temperature, for example, a thermal cycling system, a hot air heating system, an induction heating system, etc.

As the pressing system in the laminating means, it is possible to employ a known system capable of exerting a predetermined pressure, for example, a hydraulic system, a pneumatic system, a between gap pressure system, etc.

The laminating apparatus may have, at a front stage of the laminating means (at least one pair of rolls, etc.), a feeding means for feeding the respective members, and may have, at a rear stage of the laminating means, a winding-up means for winding up the bonded members. By having the feeding means for the respective members and the winding-up means, it is possible to further improve the productivity.

A specific construction of the feeding means and the winding-up means for each member may, for example, be a known winding machine which is capable of winding up each member into a roll shape, etc.

Hereinafter, with respect to the first step, the first embodiment, the second embodiment, and the third embodiment will be described, respectively, with reference to the accompanying drawings.

### First Embodiment

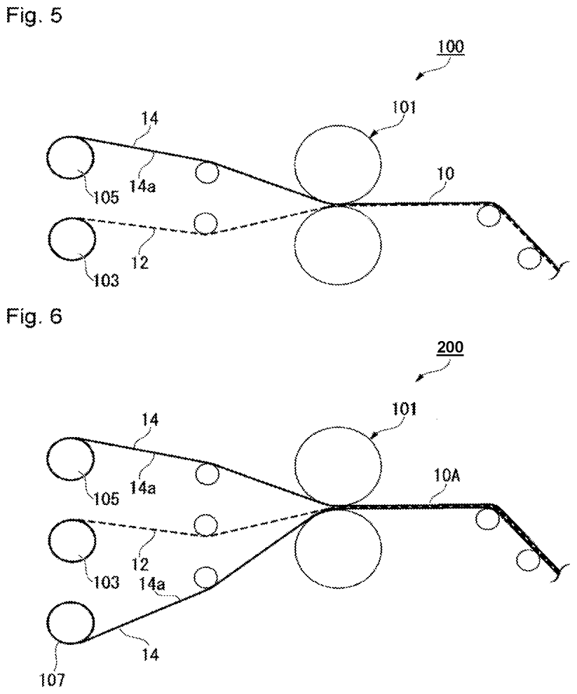

FIG. 5 is a schematic diagram showing a roll laminating apparatus 100 to be used in the first embodiment. The roll laminating apparatus 100 is provided with a pair of laminating rolls 101 (laminating means). At the front stage of the lamination rolls 101, a first feeding roll 103 (feeding means), and a second feeding roll 105 (feeding means) disposed on one side of the first feeding roll 103, are provided. Further, at the rear stage of the laminating rolls 101, a winding machine (not shown) is provided.

The laminating rolls 101 are provided with a heating mechanism, and capable of adjusting the roll surface temperature to any optional temperature. The rolls provided with a heating mechanism, may be electric heating rolls, heating medium circulation type rolls, induction heating rolls, etc. From a uniform temperature of the entire rolls, induction heating rolls are preferred.

On the first feeding roll 103, a heat-resistant substrate layer 12 (first substrate) is wound. By the first feeding roll 103, the unwinding speed of the heat-resistant substrate layer 12 is controlled, whereby it is possible to control the tension applied to the heat-resistant substrate layer 12 which is transported to the laminating rolls 101.

On the second feeding roll 105, a second substrate 14 is wound. Further, in the second feeding roll 105, the second substrate 14 is, when unwound from the second feeding roll 105, is wound up so that the first surface 14a faces the first feeding roll 103 side (heat-resistant substrate layer 12 side). By the second feeding roll 105, it is possible to control the unwinding speed of the second substrate 14, thereby to control the tension applied to the second substrate 14 which is transported to the laminating rolls 101.

In the roll laminating apparatus 100, a long heat-resistant substrate layer 12 continuously sent out from the first feeding roll 103, and a long second substrate 14 continuously sent out from the second feeding roll 105 will become a state of being overlapped between the pair of laminating rolls 101 of which the surface temperature is T₁, and will be pressed in the thickness direction at the temperature of T₁ at the time of continuously passing between the pair of the laminating rolls 101, to form a laminated body 10 (laminated body I).

The obtained laminated body 10 may be continuously wound up by the winding machine at the rear stage, or may be subjected to the second step as it is.

The surface temperature of the laminating rolls 101 (laminating roll temperature), i.e. the temperature T₁ at the time of pressing while transporting the heat-resistant substrate layer 12 and the second substrate 14, is from 0 to 100° C., preferably from 20 to 80° C., more preferably from 30 to 60° C. When the temperature T₁ is at least the above lower limit value, it is possible to obtain adhesion strength to such an extent that the heat-resistant substrate layer 12 and the second substrate 14 will not be peeled during transportation of the laminated body 10. When the temperature T₁ is at most the above upper limit value, curling of the laminated body 10 and wrinkles of the second substrate 14 will be suppressed.

The laminating roll temperature is the temperature obtained by measuring the roll surface by a contact thermocouple.

The pressure between the pair of laminating rolls 101, i.e. the pressing force at the time of laminating the heat-resistant substrate layer 12 and the second substrate 14 is preferably from 3 to 100 kN/m, more preferably from 10 to 50 kN/m. When the pressing force in the first step is at least the above lower limit value, adhesion strength to such an extent that the heat-resistant substrate layer 12 and the second substrate 14 are not peeled is easily obtainable at the time of transporting the laminated body 10. When the pressing force in the first step is at most the above upper limit value, it is possible to further suppress wrinkles of the second substrate 14.

In the first step, it is preferred that at the time of transferring the heat-resistant substrate layer 12 and the second substrate 14, the elongation of each of the heat-resistant substrate layer 12 and the second substrate 14 is made to be from 0.05 to 1.0%, and the difference in elongation between the heat-resistant substrate layer 12 and the second substrate 14 is made to be at most 0.3%. The elongation of each of the heat-resistant substrate layer 12 and the second substrate 14 is more preferably from 0.2 to 0.6%. The difference in elongation between the heat-resistant substrate layer 12 and the second substrate 14 is more preferably at most 0.2%.

The above elongation is a value obtainable by the following formula 1.

elongation (%)={tension (N) applied to the substrate during transportation/cross-sectional area (mm²) of the substrate in a direction perpendicular to the transporting direction}/elastic modulus (N/mm²) of the substrate at a temperature T₁×100 Formula 1:

The substrate in the formula is the heat-resistant substrate layer 12 or the second substrate 14.

When the elongation is at least the above lower limit value, it is possible to transport the substrate without transverse wrinkles due to sagging. When the elongation is at most the above upper limit value, it is possible to transport the substrate without formation of vertical wrinkles due to pulling too much. When the difference in elongation is at most the above upper limit value, it is possible to further suppress curling of the laminated body 10.

The tension exerted to each of the heat-resistant substrate layer 12 and the second substrate 14 at the time of transportation is obtainable by a tension pickup roll. The tensions of the respective substrates can be adjusted by the first feeding roll 103, and the second feeding roll 105.

The elastic modulus (N/mm²=MPa) of each of the heat-resistant substrate layer 12 and the second substrate 14 is obtainable by dynamic viscoelasticity measurement.

The running speed (laminating speed) at the time when the heat-resistant substrate layer 12 and the second substrate 14 pass between the pair of laminating rolls 101 may be within a range where the lamination is possible, i.e. may be, for example, from 0.5 to 5.0 m/min.

At the time when the heat-resistant substrate layer 12 and the second substrate 14 enter between the laminating rolls 101, the angle between these substrates is preferably from 3° to 45°. When the angle between the heat-resistant substrate layer 12 and the second substrate 14 is at least 3°, the air between these substrates suitably escape at the time of lamination. When it is at most 45°, wrinkles are less likely to be formed at the time of lamination.

### Second Embodiment

FIG. 6 is a schematic diagram showing a roll laminating apparatus 200 to be used in the second embodiment. Here, in the second embodiment, with respect to the constituting components corresponding to the first embodiment, detailed description thereof will be omitted by denoting the same reference numerals.

The roll laminating apparatus 200 is provided with a pair of laminating rolls 101. At the front stage of the laminating rolls 101, a first feeding roll 103, and a second feeding roll 105 and a third feeding roll 107 (feeding means) disposed respectively on the upper and lower sides thereof, are provided. Further, at the rear stage of the laminating rolls 101, a winding machine (not shown) is provided.

The roll laminating apparatus 200 is similar to the roll laminating apparatus 100 in the first embodiment, except that it is further provided with the third feeding roll 107.

On the third feeding roll 107, the second substrate 14 is wound. Further, in the third feeding roll 107, the second substrate 14 will be, when unwound from the third feeding roll 107, wound up so that the first surface 14a faces the first feeding roll 103 side (heat-resistant substrate layer 12 side). By the third feeding roll 107, it is possible to control the unwinding speed of the second substrate 14, thereby to control the tension applied to the second substrate 14 which is transported to the laminating rolls 101.

In the roll laminating apparatus 200, the long second substrate 14 continuously fed out from the third feeding roll 107, the long heat-resistant substrate layer 12 continuously fed out from the first feeding roll 103 and another long second substrate 14 continuously fed out from the second feeding roll 105, will become in an overlapped state between the pair of laminating rolls 101 of which the surface temperature is T₁, and will be pressed in the thickness direction at the temperature of T₁ at the time of continuously passing between the pair of laminating rolls 101, to form a laminated body 10A (laminated body I).

The obtained laminated body 10A may be continuously wound up by a winding machine of the rear stage, or may be subjected to a second step as it is.

The laminating roll temperature (temperature T₁) is the same as in the first embodiment, and its preferred embodiments are also the same. Further, the pressing force, the elongation of each the heat-resistant substrate layer 12 and the second substrate 14 at the time of transporting the heat-resistant substrate layer 12 and the second substrate 14, the difference in elongation between the heat-resistant substrate layer 12 and the second substrate 14, and the respective preferred values, are also the same as in the first embodiment.

Here, the elongation of the second substrate 14 in the second embodiment is the elongation of each of the two second substrates 14. The elongations of the two second substrates 14 may be the same or may be different, and with a view to suppressing the curling, they are preferably the same.

### Third Embodiment

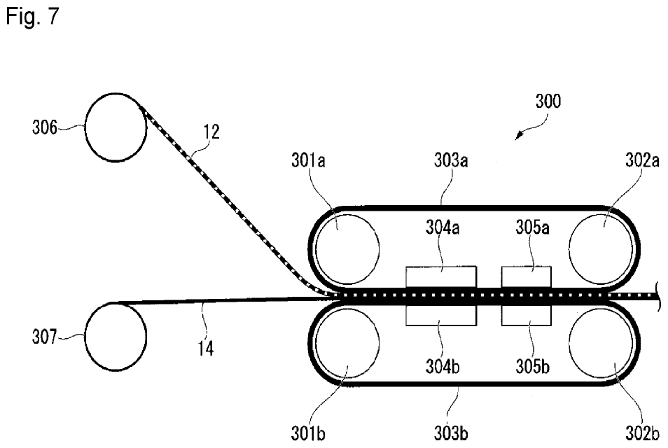

FIG. 7 is a schematic diagram showing a double belt pressing apparatus 300 to be used in the third embodiment. The double belt pressing apparatus 300 is constituted by a pair of a front upper drum 301a and a front lower drum 301b, a pair of a rear upper drum 302a and a rear lower drum 302b, and further, belts 303a and 303b which are, respectively, put with a tension around an assembly of the two upper drums and an assembly of the two lower drums. In FIG. 7, the two front drums 301a and 301b are heated drums, and the two rear drums 302a and 302b are cooled drums. The heat-pressing device of this double belt pressing apparatus 300 is composed of heat-pressing members 304a and 304b provided on the upper and lower sides, and constructed so that by the approach of the upper and lower heat-pressing members 304a and 304b to each other, a pressure is exerted to the laminated body which is transported as sandwiched by the upper and lower belts 303a and 303b in the double belt pressing apparatus. Further, in the double belt pressing apparatus 300 in FIG. 7, a press-cooling device 305a and 305b are provided at the rear side of the heat-pressing device, whereby the laminated body press-treated at a high temperature is cooled.

At the front stage of the double belt pressing apparatus 300, a first feeding roll 306 (feeding means) and a second feeding roll 307 (feeding means) disposed on one side of the first feeding roll 306, are provided. Further, at the rear stage of the rear drums 302a and 302b, a winding machine (not shown) is provided.

On the first feeding roll 306, the heat-resistant substrate layer 12 (first substrate) is wound. By the first feeding roll 306, it is possible to control the unwinding speed of the heat-resistant substrate layer 12, thereby to control the tension applied to the heat-resistant substrate layer 12 which is transported to the belts 303a and 303b.

On the second feeding roll 307, the second substrate 14 is wound. Further, in the second feeding roll 307, the second substrate 14 will be, when unwound from the second feeding roll 307, wound up so that the first surface 14a faces the first feeding roll 306 side (heat-resistant substrate layer 12 side). By the second feeding roll 306, it is possible to control the unwinding speed of the second substrate 14, thereby to control the tension applied to the second substrate 14 to be transported to the belts 303a and 303b.

In the double belt pressing apparatus 300, the long heat-resistant substrate layer 12 continuously fed out from from the first feeding roll 306, and the long second substrate 14 continuously fed out from the second feeding roll 307, will become in an overlapped state between the belts 303a and 303b of which the surface temperature is T₁, and will be pressed in the thickness direction at the temperature of T₁ at the time when continuously passing between the belts 303a and 303b, to form a laminated body 10 (laminated body I).

The obtained laminated body 10 may be continuously wound by a winding machine at the rear stage, or may be directly subjected to the second step as it is.

The belt temperature (temperature Ti) is the same as in the first embodiment, and its preferred embodiments are also the same. Further, the pressing force, the elongation of each of the heat-resistant substrate layer 12 and the second substrate 14 at the time of transporting the heat-resistant substrate layer 12 and the second substrate 14, the difference in elongation between the heat-resistant substrate layer 12 and the second substrate 14, and the respective preferred values, are also the same as in the first embodiment.

In the foregoing, the first step has been described with reference to the first to third embodiments, but the first step of the present invention is not limited to the above embodiments. The respective constructions in the above embodiments and their combinations are merely exemplary, and within the scope of the present invention, additions, omissions, substitutions and other changes of the constructions are possible.

For example, in the roll laminating apparatus 100 and 200, at the front stage of the pair of laminating rolls 101, a preheating means (preheating roll, preheater, etc.) may be provided, so that the heat-resistant substrate layer 12 and/or the second substrate 14 be preheated. In the case of preheating, the preheating temperature is preferably from 20 to 100° C.

Further, the pressing may be conducted two or more times. For example, adjacent to either one of two rolls which constitute the pair of laminating rolls 101, one roll may be disposed, so that the substrates to be laminated be passed between such three rolls under pressure.

As the first substrate, instead of the heat-resistant substrate layer 12, a metal foil layer may be used, or one composed of a heat-resistant substrate layer and a metal foil layer may be used.

### (Second Step)

In the second step, a laminated body II is obtained by disposing a third substrate on the second substrate of the laminated body I obtained in the first step, and while transporting the laminated body I and the third substrate, pressing them for lamination in the thickness direction (laminating direction) at a temperature T₂ of at least the melting point of the fluororesin contained in the second substrate.

Like the first step, the second step is preferably conducted continuously by means of a laminating apparatus provided with at least one pair of laminating means. The laminating apparatus may be the same one as exemplified in the description of the first step.

In a case where the laminated body I is one in which the second substrate is laminated on one side of the first substrate, and a third substrate is to be laminated on one side (second substrate side) of the laminated body I, for example, by using the same roll laminating apparatus as the roll laminating apparatus 100 as shown in FIG. 5, it is possible to carry out the second step. However, in this case, the first feeding roll 103 is assumed to be one on which the laminated body I is wound, and the second feeding roll 105 is assumed to be one on which the third substrate is wound. Further, in the first feeding roll 103, the laminated body I is one which will be, when unwound from the first feeding roll 103, wound up so that the second substrate side (the second surface of the second substrate) faces the second feeding roll 105 side (the third substrate side).

In the roll laminating apparatus 100, the long laminated body I continuously fed out from the first feeding roll 103, and the long third substrate continuously fed out from the second feeding roll 105 will be in an overlapped state between the pair of laminating rolls 101 of which the surface temperature is T₂, and will be pressed in the thickness direction at the temperature of T₂ at the time of continuously passing between the pair of laminating rolls 101, to form a laminated body II. The obtained laminated body II can be continuously wound up by a winding machine at the rear stage. At that time, if the laminated body I is a laminated body 10, and the third substrate is a metal foil layer 16, a laminated body 20 as shown in FIG. 2 is obtainable.

In a case where the laminated body I is one in which a second substrate is laminated on both sides of the first substrate, and a third substrate is to be laminated on both sides of the laminated body I, for example, by using the same roll laminating apparatus similar to the roll laminating apparatus 200 as shown in FIG. 6, it is possible to carry out the second step. However, in this case, the first feeding roll 103 is one on which the laminated body I is wound, and the second feeding roll 105 and the third feeding roll 107 are, respectively, ones on which the third substrate is wound.

In the roll laminating apparatus 200, the long third substrate continuously fed out from the third feeding roll 107, the long laminated body I continuously fed out from the first feeding roll 103, and the long third substrate continuously fed out from the second feeding roll 105, will be in an overlapped state between the pair of laminating rolls 101 of which the surface temperature is T₂, and will be pressed in the thickness direction at the temperature T₂ at the time of continuously passing between the pair of laminating rolls 101, to form a laminated body II. The obtained laminated body II can be continuously wound up by a winding machine at the rear stage. At that time, if the laminated body I is a laminated body 10A, and the two third substrates are, respectively, metal foil layers 16, a laminated body 20A as shown in FIG. 4 is obtainable.

The temperature T₂ at the time of pressing while transporting the laminated body I and the third substrates 2 is at least the melting point of the fluororesin contained in the second substrates in the laminated body I, preferably at least (the melting point+15° C.), more preferably at least (the melting point+30° C.). When the temperature T₂ is at least the above lower limit value, the second substrate will melt, and the adhesion strength between the first substrate and the third substrate will be excellent. In particular, when the fluororesin has adhesive functional groups, more excellent adhesion strength will be exhibited. Further, in the laminated body I, wrinkles of the second substrate will be suppressed, i.e. at the time of lamination in the second step, on both sides of the second substrate, another substrate (the first substrate or the third substrate) is in contact, whereby wrinkles will be hardly formed in the second substrate even if heated at a temperature above the melting point of the fluororesin.

The temperature is, from the viewpoint of preventing oxidation of the metal foil layer, preferably at most 400° C., more preferably at most 380° C.

However, in a case where vacuum plasma treatment is applied to the second substrate, the temperature T₂ is at least the melting point of the fluororesin contained in the second substrate of the laminated body I, preferably at least (the melting point±0° C.), more preferably (the melting point+5° C.). When the temperature T₂ is at least the above lower limit value, the vacuum plasma treated layer of the second substrate will be activated, and the adhesion strength between the second substrate and the third substrate will be excellent. As the temperature T₂ decreases, it is possible to obtain a laminated body II of which a dimensional change is small.

Further, the same applies also in a case where vacuum plasma treatment is applied to the heat-resistant resin films of the first substrate and the third substrate, and at least (the melting point of ±0° C.) is preferred, and at least (the melting point+5° C.) is more preferred. When the temperature T₂ is at least the above lower limit value, the vacuum plasma treated layers of the first substrate and the third substrate will be activated, and the adhesion strength between the second substrate, and the first substrate and the third substrate, will be excellent. As the temperature T₂ decreases, it is possible to obtain a laminated body II of which a dimensional change is small.

Further, at the time of being in contact the high temperature rolls in the second step, if the heat-resistant resin film has a high water absorption and has in fact water absorbed, foaming will occur. It is preferred to use a heat-resistant resin film with a low water absorption and to heat it immediately prior to being in contact with the high temperature rolls to remove water, and by taking these measures, it is possible to prevent foaming.

The pressure between the pair of laminating rolls 101, i.e. the pressing force at the time of laminating the laminated body I and the third substrate, may be within a range where the lamination is possible, and may be, for example, from 10 to 100 kN/m.

The running speed (laminating speed) at the time when the laminated body I and the third substrate pass between the pair of laminating rolls 101, may be within a range where the lamination is possible, and may be, for example, from 0.5 to 5.0 m/min.

At the time when the laminated body I and the third substrate enter the laminating rolls, the angle between these substrates may be within a range where the lamination is possible, and may be, for example, from 3° to 45°.

The method for producing a laminated body of the present invention may further have other steps other than the first and second steps, as the case requires. Other steps may, for example, be a step of contacting the laminated body II after the second step, to laminating rolls heated to at least the melting point of the second substrate without applying pressure, to improve adhesion between the second substrate and another layer, etc.

In the method for producing a laminated body of the present invention, the temperature T₁ at the time of laminating the first substrate and the second substrate in the first step is from 0 to 100° C., whereby it is possible to prevent formation of wrinkles in the second substrate (fluororesin layer), or to prevent curling of the laminated body I. Further, the wetting tension of the first surface of the second substrate (the surface laminated with the first substrate) is from 30 to 60 mN/m, and the wetting tension of the second surface on the opposite side (the surface in contact with the laminating means) is smaller by at least 2 mN/m than the wetting tension of the first surface, whereby it is possible to prevent delamination between the first substrate and the second substrate. Therefore, it is possible to obtain a laminated body I with little wrinkles, curling or delamination. Further, when the third substrate is laminated on the laminated body I, it is possible to obtain a laminated body II with little wrinkles or delamination.

### <Method for Producing Flexible Printed Circuit Board>

A flexible printed circuit board can be produced via steps of obtaining, as the laminated body II, a laminated body of which at least one of the outermost layers is a metal foil layer, by using the method for producing a laminated body of the present invention, and removing a portion of the metal foil layer of the outermost layers of said laminated body by etching to form a patterned circuit.

Examples of the layered structure of the laminated body II of which at least one of the outermost layers is a metal foil layer, are as described above.

For example, in the case of laminating the second substrate on one side of the first substrate in the first step, the laminated body II of which at least one of the outermost layers is a metal foil layer, can be obtained by using a metal foil layer as at least one of the first substrate and the third substrate. In a case where the second substrate is laminated on both sides of the first substrate in the first step, and the second substrate is laminated on both sides of the laminated body I in the second step, it can be obtained by using a metal foil layer as the third substrate. Instead of the metal foil layer, a substrate composed of a heat-resistant substrate layer and a metal foil layer, in which the outermost layer on the side opposite to the second substrate side is a metal foil layer, may be used.

As the dimensional change of the laminated body II is lower, warpage or defect in circuit after the step of forming a pattern circuit, will be less. The dimensional change of the laminated body II is preferably within ±0.15%, more preferably within ±0.08%. The flexible printed circuit board in the present invention may be one having various size-reduced or highly densified parts mounted.

In the method for producing a flexible printed circuit board of the present invention, the method for producing a laminated body of the present invention is employed, whereby it is possible to obtain a flexible printed circuit board with little wrinkles or delamination.

### EXAMPLES

In the following, the present invention will be described in detail with reference to Examples. However, the present invention should not be construed as being limited to the following Examples.

Here, Ex. 1 to 22 are Examples of the present invention, and Ex. 23 to 26 are Comparative Examples. The evaluation methods and materials used in each Ex. are shown below.

### (Evaluation of Wetting Tension)

The wetting tension of each of the first surface and the second surface of a fluororesin film was measured in accordance with JIS K6768:1999 by using a liquid mixture for wetting tension test (manufactured by Wako Pure Chemical Industries, Ltd.).

### (Evaluation of Wrinkles)

A laminated body (laminated body I or laminated body II) was unwound, and the appearance of its portion corresponding to 5 m in length was visually observed, whereby the presence or absence and the state of wrinkles in the second substrate (fluororesin film) as an interlayer, were evaluated. The results were judged by the following standards

○ (good): Wrinkles are not observed.

Δ (acceptable): Wrinkles are not observed, but crease marks are observed.

× (poor): The film is broken, and a wrinkled portion is observed at least at one place.

### (Evaluation Method for Curling)

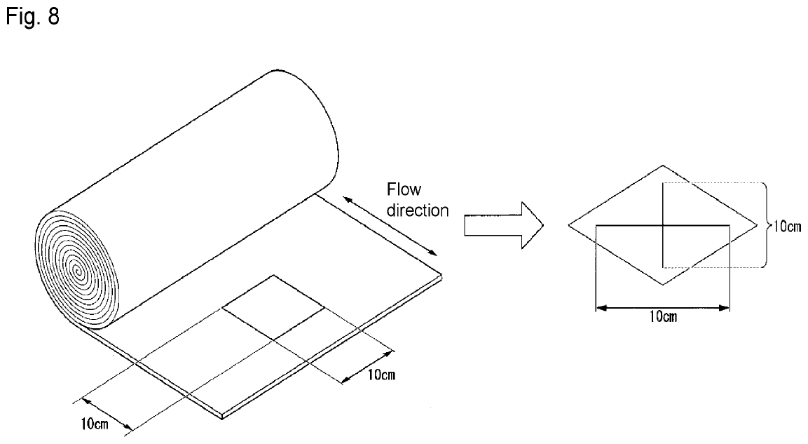

As shown in FIG. 8, a 10 cm×10 cm square sample of a laminated body I was cut out, and the four sides of the obtained sample were fixed to a pedestal by an adhesive tape, whereupon two cut lines with a length of 10 cm were imparted along the diagonal lines. Thus, triangular four tongues were formed whose vertices are at a portion where the two cut lines intersect. Then, the presence or absence of curling of the four tongues was observed, and with respect to a curled one, the curling height (the height from the pedestal surface up to the highest position of the curled tongue) was measured with a ruler. The largest value among the curling heights of the four tongues was adopted as the curling height of the laminated body. In a case where curling was not observed, the curling height was indicated to be 0 mm.

### (Evaluation of Peeling)

A laminated body (laminated body I or laminated body II) was unwound, and the appearance of its portion corresponding to 5 m in length of was visually observed, whereby the presence or absence of peeling (bubbles) between the layers was evaluated. Further, in a case where the peeling was observed, by a microscope, the diameter φ as converted as a perfect circle of the peeled portion was measured. The results were judged by the following standards.

○ (good): Peeling is not observed.

Δ (acceptable): Peeling of less than φ1 mm is observed at least at one place and less than 10 places, and peeling of at least φ1 mm is not observed.

× (poor): Peeling of less than φ1 mm is observed at least at 10 places, or peeling of at least φ1 mm is observed at least at one place.

### (Evaluation of Adhesion Strength)

A laminated body I was cut out in a length of 150 mm and a width of 10 mm, to prepare an evaluation sample. Peeling between the first substrate and the second substrate was carried out from one end in the longitudinal direction of the evaluation sample to a position of 50 mm. Then, using a tensile tester, peeling was carried out so as to be 90° at a tensile rate of 50 mm/min, and the average load in the measured distance of from 20 mm to 80 mm was adopted as the peel strength (N/cm).

With respect to a laminated body II, the peel strength was measured in the same manner as described above, except that peeling was carried out between the first substrate and the third substrate. In this case, as between the peel strength between the first substrate and the second substrate, and the peel strength between the third substrate and the second substrate, the weaker peel strength is measured.

### (Dimensional Change Rate)

With respect to the dimensional change rate of a laminated body, a test was carried out in accordance with JIS C6471. The dimensional change rate before and after etching of a laminated body II cut out in a rectangular shape of vertical 240 mm×horizontal 300 mm, and the dimensional change rate after heating a laminated body II after etching, at 150° C. for 30 minutes, were measured. The final dimensional change rate was obtained by the following formula.

(Dimensional change rate % in MD direction)={(Dimension in MD direction after heating at 150° C. for 30 minutes)−(Dimension in MD direction of the laminated body II before etching)}/(Dimension in MD direction of the laminated body II before etching)×100

(Dimensional change rate% in TD direction)={(Dimension in TD direction after heating at 150° C. for 30 minutes)−(Dimension in TD direction of the laminated body II before etching)}/(Dimension in TD direction of the laminated body II before etching)×100

(Dimensional change rate %)={(Dimensional change rate % in MD direction)+(Dimensional change rate % in TD direction)}/2

### [Materials]

Fluororesin A: A fluorinated resin produced as described in paragraphs [0111] to [0113] of WO 2016/104297. Copolymer composition (molar ratio): TFE units/NAH units/PPVE units=97.9/0.1/2.0, melting point: 305° C., melt flow rate: 11.0 g/10 min, fluorine content: 75 mass %.

Fluororesin B: A fluorinated resin produced in the same manner as the fluororesin A except that the amount of the NAH solution continuously charged into the polymerization vessel was changed to an amount corresponding to 0.2 mol % to the number of moles of TFE to be charged during the polymerization. Copolymer composition (molar ratio): TFE units/NAH units/PPVE units=97.8/0.2/2.0, melting point: 305° C., melt flow rate: 11.0 g/10 min, fluorine content: 75 mass %.

Fluororesin C: A fluorinated resin produced in the same manner as the fluororesin A except that the amount of the NAH solution continuously charged into the polymerization vessel was changed to an amount corresponding to 0.3 mol % to the number of moles of TFE to be charged during the polymerization. Copolymer composition (molar ratio): TFE units/NAH units/PPVE units=97.7/0.3/2.0, melting point: 305° C., melt flow rate: 11.0 g/10 min, fluorine content: 75 mass %.

Fluororesin D: Commercially available fluororesin. Copolymer composition (molar ratio): TFE units/PPVE units=98.0/2.0, melting point: 310° C., melt flow rate: 11.0 g/10 min, fluorine content: 75 mass %.

### (Fluororesin Film 1)

The fluororesin A was extrusion-molded into a film shape at a die temperature of 340° C. by using a 65 mmφ single screw extruder having a coat hanger die of 750 mm in width, and, immediately after the molding, corona discharge treatment was applied on one side with a discharge amount of 30 W·min/m², to obtain a fluororesin film 1 having a thickness of 25 μm and a width of 250 mm. The wetting tension of the first surface (corona discharge treated surface) of the fluororesin film 1 was 30 mN/m, and the wetting tension of the second surface (not corona discharge treated surface) was less than 22.6 mN/m.

### (Fluororesin Film 2)

In the same manner as the fluororesin film 1 except that the discharge amount was changed to 40 W·min/m², a fluororesin film 2 having a thickness of 25 μm with the wetting tension of the first surface being 40 mN/m was obtained.

### (Fluororesin Film 3)

In the same manner as the fluororesin film 1 except that the discharge amount was changed to 60 W·min/m², a fluororesin film 3 having a thickness of 25 μm with the wetting tension of the first surface being 50 mN/m was obtained.

### (Fluororesin Film 4)

In the same manner as the fluororesin film 1 except that no corona discharge treatment was applied, a fluororesin film 4 having a thickness of 25 μm with the wetting tension of the first surface being 22.6 mN/m was obtained.

### (Fluororesin Film 5)

In the same manner as the fluororesin film 1 except that the discharge amount was changed to 100 W·min/m², a fluororesin film 5 having a thickness of 25 μm with the wetting tension of the first surface being 70 mN/m was obtained.

### (Fluororesin Film 6)

In the same manner as the fluororesin film 3 except that the fluororesin B was used, a fluororesin film 6 having a thickness of 25 μm with the wetting tension of the first surface being 50 mN/m was obtained.

### (Fluororesin Film 7)

In the same manner as the fluororesin film 3 except that the fluororesin C was used, a fluororesin film 7 having a thickness of 25 μm with the wetting tension of the first surface being 50 mN/m was obtained.

### (Fluororesin Film 8)

In the same manner as the fluororesin film 3 except that the fluororesin D was used, a fluororesin film 8 having a thickness of 25 μm with the wetting tension of the first surface being 50 mN/m was obtained.

### (Fluororesin Film 9)

In the same manner as the fluororesin film 3 except that the thickness was changed, a fluororesin film 9 having a thickness of 12.5 μm with the wetting tension of the first surface being 50 mN/m was obtained.

### (Fluororesin Film 10)

In the same manner as the fluororesin film 1 except that both surfaces were corona discharge-treated with a discharge amount 30 W·min/m² and the wetting tensions of both surfaces were made to be 30 mN/m, a fluororesin film 10 having a thickness of 25 μm was obtained.

### (Fluororesin Film 11)

Only the first surface of the fluororesin film 4 was plasma-treated at a discharge power density of 300 W·min/m² by applying a high frequency voltage of 110 KHz in a carbon dioxide atmosphere under a pressure of 20 Pa, to obtain a fluororesin film 11 with the wetting tension of the first surface being 50 mN/m.

### (Heat-Resistant Substrate 1)

A polyimide film having a thickness of 25 μm (Kaneka Corporation trade name: PIXEO BP, thermosetting polyimide with a thermoplastic polyimide layer) was prepared. The water absorption rate was 1.3%.

### (Heat-Resistant Substrate 2)

A polyimide film having a thickness of 25 μm (Ube Industries, Ltd. trade name: UPILEX VT, thermosetting polyimide with a thermoplastic polyimide layer) was prepared. The water absorption rate was 1.4%.

### (Heat-Resistant Substrate 3)

A polyimide film having a thickness of 25 μm (Ube Industries, Ltd. trade name: UPILEX NVT, thermosetting polyimide with a thermoplastic polyimide layer) was prepared. The water absorption rate was 1.4%.

### (Heat-Resistant Substrate 4)

A liquid crystal polyester film having a thickness of 25 μm (manufactured by Kuraray Co., Ltd., trade name: CTZ-25KS, liquid crystal polyester) was prepared. The water absorption rate was 0.1%.

### (Heat-Resistant Substrate 5)

One having corona discharge treatment with a discharge amount of 30 W/(m²·min) applied to a polyimide film having a thickness of 25 μm (Ube Industries, Ltd. trade name: UPILEX S, thermosetting polyimide), was prepared. The water absorption rate was 1.4%.

### (Heat-Resistant Substrate 6)

One having atmospheric pressure plasma treatment applied to a polyimide film having a thickness of 25 μm (Ube Industries, Ltd. trade name: UPILEX S, thermosetting polyimide) under the following conditions, was prepared. The water absorption rate was 1.4%.
Plasma treatment conditions:
   Gas species: Ar gas 99.0 atm %, nitrogen gas 0.5 atm %, hydrogen gas 0.5 atm %,
   Treatment frequency: 30 kHz,
   Atmospheric pressure: 102 kPa,
   Discharge power density: 300 W·min/m²

### (Heat-Resistant Substrate 7)

One having vacuum plasma treatment applied to a polyimide film having a thickness of 25 μm (Ube Industries, Ltd. trade name: UPILEX S, thermosetting polyimide) under the same conditions as for the above heat-resistant substrate 6 except that the atmospheric pressure was changed to 20 Pa instead of 102 kPa, was prepared. The water absorption rate was 1.4%.

(Heat-Resistant substrate 8)

One having vacuum plasma treatment applied to a liquid crystal polyester film having a thickness of 25 μm (manufactured by Kuraray Co., Ltd., trade name: CTZ-25KS, liquid crystal polyester) under the same conditions as for the heat-resistant substrate 6, was prepared. The water absorption rate was 0.1%.

### (Heat-Resistant Substrate 9)

A polyimide film having a thickness of 25 μm (Kaneka Corporation trade name: Apical NPI, thermosetting polyimide) was prepared. The water absorption rate was 1.7%.

### (Metal Foil 1)

A copper foil having a thickness of 12 μm (Fukuda Metal Foil & Powder Co., Ltd., trade name: CF-T4X-SV, electrolytic copper foil Rzjis 1.1 μm) was prepared.

### Ex. 1

### (First Step)

By using a roll laminating apparatus having a structure shown in FIG. 5, under the following conditions, a laminated body I of a two-layer structure wherein the fluororesin film 1 (second substrate) was laminated on one side of the heat-resistant substrate 1 (first substrate), was produced, and evaluations of wrinkles, curling, peeling and adhesion strength were carried out. The results are shown in Table 1.

The surface temperature (laminating temperature) of the pair of laminating rolls 101 (metal rolls) was set to be 20° C. The pressing force was set to be 15 kN/m, and the transportation speed (lamination speed) of the first substrate and the second substrate was set to be 3 m/m in. The tension applied to the first substrate was set to be 200 N. The tension applied to the second substrate was set to be 20 N.

### (Second Step)

Then, by using a roll laminating apparatus having a structure shown in FIG. 5, under the following conditions, a laminated body II of a three-layer structure wherein the metal foil 1 (third substrate) was laminated to the surface of the second substrate side of the laminated body I obtained as described above, was produced, and evaluations of wrinkles, peeling and adhesion strength were carried out. The results are shown in Table 1.

The surface temperature (laminating temperature) of the pair of laminating rolls 101 (metal rolls) was set to be 360° C. The pressing force was set to be 5 kN/m, and the transportation speed (lamination speed) of the laminated body I and the third substrate was set to be 1 m/m in.

### Ex. 2

In the same manner as in Ex. 1 except that, as the second substrate, the fluororesin film 2 was used instead of the fluororesin film 1, a laminated body I and a laminated body II were produced, and the evaluations were carried out. The results are shown in Table 1.

### Ex. 3

In the same manner as in Ex. 1 except that, as the second substrate, the fluororesin film 3 was used instead of the fluororesin film 1, a laminated body I and a laminated body II were produced, and the evaluations were carried out. The results are shown in Table 1.

### Ex. 4

In the same manner as in Ex. 3 except that in the first step, the laminating temperature was set to be 80° C., the tension applied to the first substrate was set to be 190 N, and the tension applied to the second substrate was set to be 13 N, a laminated body I and a laminated body II were produced, and the evaluations were carried out. The results are shown in Table 1.

### Ex. 5

In the same manner as in Ex. 3 except that in the first step, the laminating temperature was set to be 100° C., and the tension applied to the second substrate was set to be 8 N, a laminated body I and a laminated body II were produced, and the evaluations were carried out. The results are shown in Table 1.

### Ex. 6

In the same manner as in Ex. 3 except that in the first step, the tension applied to the second substrate was set to be 30 N, a laminated body I and a laminated body II were produced, and the evaluations were carried out. The results are shown in Table 1.

### Ex. 7

In the same manner as in Ex. 3 except that in the first step, the tension applied to the second substrate was set to be 300 N, a laminated body I and a laminated body II were produced, and the evaluations were carried out. The results are shown in Table 2.

### Ex. 8

In the same manner as in Ex. 3 except that in the first step, the pressing force was set to be 2 kN/m, a laminated body I and a laminated body II were produced, and the evaluations were carried out. The results are shown in Table 2.

### Ex. 9

In the same manner as in Ex. 3 except that in the first step, the pressing force was set to be 40 kN/m, a laminated body I and a laminated body II were produced, and the evaluations were carried out. The results are shown in Table 2.

### Ex. 10

In the same manner as in Ex. 3 except that in the first step, the pressing force was set to be 110 kN/m, a laminated body I and a laminated body II were produced, and the evaluations were carried out. The results are shown in Table 2.

### Ex. 11

In the same manner as in Ex. 3 except that as the first substrate, the metal foil 1 was used instead of the heat-resistant substrate 1, and in the first step, the tension applied to the first substrate was set to be 1,000 N, and as the third substrate, the heat-resistant substrate 1 was used instead of the metal foil, a laminated body I and a laminated body II were produced, and the evaluations were carried out. The results are shown in Table 2.

### Ex. 12

### (First Step)

By using a roll laminating apparatus having a structure shown in FIG. 6, under the following conditions, a laminated body I of a three-layer structure wherein the fluororesin film 3 (second substrate) was laminated on both sides of the heat-resistant substrate 1 (first substrate), was produced, and evaluations of wrinkles, curling, peeling and adhesion strength were carried out. The results are shown in Table 2.

The surface temperature (laminating temperature) of the pair of laminating rolls 101 (metal rolls) was set to be 20° C. The pressing force was set to be 15 kN/m, and the transportation speed (lamination speed) of the first substrate and the second substrate was set to be 3 m/min. The tension applied to the first substrate was set to be 200 N. The tension applied to each of the two second substrates was set to be 20 N.

### (Second Step)

Then, by using a roll laminating apparatus having a structure shown in FIG. 6, under the following conditions, a laminated body II of a five-layer structure wherein the metal foil 1 (third substrate) was laminated to both surfaces of the laminated body I obtained as described above, was produced, and evaluations of wrinkles, peeling and adhesion strength were carried out. The results are shown in Table 2.

The surface temperature (laminating temperature) of the pair of laminating rolls 101 (metal rolls) was set to be 360° C. The pressing force was set to be 5 kN/m, and the transportation speed (lamination speed) of the laminated body I and the third substrate was set to be 1 m/min.

### Ex. 13

In the same manner as in Ex. 3 except that as the second substrate, the fluororesin film 6 was used instead of the fluororesin film 3, a laminated body I and a laminated body II were produced, and the evaluations were carried out. The results are shown in Table 3.

### Ex. 14

In the same manner as in Ex. 3 except that as the second substrate, the fluororesin film 7 was used instead of the fluororesin film 3, a laminated body I and a laminated body II were produced, and the evaluations were carried out. The results are shown in Table 3.

### Ex. 15

In the same manner as in Ex. 3 except that as the second substrate, the fluororesin film 8 was used instead of the fluororesin film 3, a laminated body I and a laminated body II were produced, and the evaluations were carried out. The results are shown in Table 3.

### Ex. 16

In the same manner as in Ex. 3 except that as the second substrate, the fluororesin film 9 was used instead of the fluororesin film 3, and in the first step, the tension applied to the second substrate was set to be 10 N, a laminated body I and a laminated body II were produced, and the evaluations were carried out. The results are shown in Table 3.

### Ex. 17

In the same manner as in Ex. 3 except that as the first substrate, the heat-resistant substrate 4 was used instead of the heat-resistant substrate 1, and in the first step, the tension applied to the first substrate was set to be 110 N, a laminated body I and a laminated body II were produced, and the evaluations were carried out. The results are shown in Table 3.

### Ex. 18

In the same manner as in Ex. 3 except that as the first substrate, the heat-resistant substrate 2 was used instead of the heat-resistant substrate 1, a laminated body I and a laminated body II were produced, and the evaluations were carried out. The results are shown in Table 4.

### Ex. 19

In the same manner as in Ex. 3 except that as the first substrate, the heat-resistant substrate 3 was used instead of the heat-resistant substrate 1, a laminated body I and a laminated body II were produced, and the evaluations were carried out. The results are shown in Table 4.

### Ex. 20

In the same manner as in Ex. 3 except that as the second substrate, the fluororesin film 11 was used instead of the fluororesin film 3, and the laminating temperature in the second step was set to be 305° C., a laminated body I and a laminated body II were produced, and the evaluations were carried out. The results are shown in Table 4.

### Ex. 21

In the same manner as in Ex. 3 except that as the first substrate, the heat-resistant substrate 4 was used instead of the heat-resistant substrate 1, and as the second substrate, the fluororesin film 11 was used instead of the fluororesin film 3, and the laminating temperature of the second step was set to be 305° C., a laminated body I and a laminated body II were produced, and the evaluations were carried out. The results are shown in Table 4.

### Ex. 22

### (First Step)

By using the double belt pressing apparatus having the construction as shown in FIG. 7, under the following conditions, a laminated body I of a two-layer structure, wherein the fluororesin film 3 (second substrate) was laminated on one side of the heat-resistant substrate 2 (first substrate), was produced, and evaluations of wrinkles, curling, peeling and adhesion strength were carried out. The results are shown in Table 4.

The surface temperature (laminating temperature) of the pair of belts 303a and 303b, was set to be 20° C. The pressing force was set to be 15 kN/m, and the transporting speed (lamination speed) of the first substrate and the second substrate was set to be 3 m/m in. The tension applied to the first substrate was set to be 200 N. The tension applied to the second substrate was set to be 20 N.

### (Second Step)

Then, by using the double-belt apparatus having the construction as shown in FIG. 7, under the following conditions, a laminated body II of a three-layer structure wherein the metal foil 1 (third substrate) was laminated to the surface of the second substrate side of the laminated body I obtained as described above, was produced, and evaluations of wrinkles, peeling and adhesion strength were carried out. The results are shown in Table 4.

The surface temperature (laminating temperature) of the pair of belts 303a and 303b was set to be 360° C. The pressing force was set to be 5 kN/m, and the transporting speed (lamination speed) of the laminated body I and the third substrate was set to be 1 m/m in.

### Ex. 23

In the same manner as in Ex. 3 except that as the second substrate, the fluororesin film 4 was used instead of the fluororesin film 3, a laminated body I and a laminated body II were produced, and the evaluations were carried out. The results are shown in Table 5.

### Ex. 24

In the same manner as in Ex. 3 except that as the second substrate, the fluororesin film 5 was used instead of the fluororesin film 3, a laminated body I and a laminated body II were produced, and the evaluations were carried out. The results are shown in Table 5.

### Ex. 25

In the same manner as in Ex. 3 except that in the first step, the laminating temperature was set to 120° C., a laminated body I and a laminated body II were produced, and the evaluations were carried out. The results are shown in Table 5.

### Ex. 26

In the same manner as in Ex. 3 except that as the second substrate, the fluororesin film 10 was used instead of the fluororesin film 3, a laminated body I and a laminated body II were produced, and the evaluations were carried out. The results are shown in Table 5.

### Ex. 27

In the same manner as in Ex. 1 except that as the first substrate, the heat-resistant substrate 5 was used instead of the heat-resistant substrate 1, a laminated body I and a laminated body II were produced, and the evaluations were carried out. The results are shown in Table 6.

### Ex. 28

In the same manner as in Ex. 1 except that as the first substrate, the heat-resistant substrate 6 was used instead of the heat-resistant substrate 1, a laminated body I and a laminated body II were produced, and the evaluations were carried out. The results are shown in Table 6.

### Ex. 29

In the same manner as in Ex. 1 except that as the first substrate, the heat-resistant substrate 7 was used instead of the heat-resistant substrate 1, a laminated body I and a laminated body II were produced, and the evaluations were carried out. The results are shown in Table 6.

### Ex. 30

In the same manner as in Ex. 1 except that as the second substrate, the heat-resistant substrate 8 was used instead of the heat-resistant substrate 1, a laminated body I and a laminated body II were produced, and the evaluations were carried out. The results are shown in Table 6.

### Ex. 31

In the same manner as in Ex. 1 except that as the second substrate, the heat-resistant substrate 9 was used instead of the heat-resistant substrate 1, a laminated body I and a laminated body II were produced, and the evaluations were carried out. The results are shown in Table 6.

Tables 1 to 6 show the construction and production conditions of the laminated body I produced in the first step of each of Ex. 1 to 31, and the construction of the laminated body II produced in the second step. In Tables 1 to 6, the elastic modulus and the elongation of the first substrate and the second substrate, and (elongation of the second substrate−elongation of the first substrate), are, respectively, values measured at the laminating temperature.

TABLE 1

| | | | Ex. 1 | Ex. 2 | Ex. 3 | Ex. 4 | Ex. 5 | Ex. 6 |
|---|---|---|---|---|---|---|---|---|
| Lamination method | | | Roll | Roll | Roll | Roll | Roll | Roll |
| | | | laminate | laminate | laminate | laminate | laminate | laminate |
| First | Laminated body I | | Laminated | Laminated | Laminated | Laminated | Laminated | Laminated |
| step | | | body 1 | body 2 | body 3 | body 4 | body 5 | body 6 |
| | Construction of | Second substrate | Fluororesin | Fluororesin | Fluororesin | Fluororesin | Fluororesin | Fluororesin |
| | laminated body I | | film 1 | film 2 | film 3 | film 3 | film 3 | film 3 |
| | | First substrate | Heat- | Heat- | Heat- | Heat- | Heat- | Heat- |
| | | | resistant | resistant | resistant | resistant | resistant | resistant |
| | | | substrate 1 | substrate 1 | substrate 1 | substrate 1 | substrate 1 | substrate 1 |
| | | Second substrate | — | — | — | — | — | — |
| | Wetting tension of | First surface | 30 | 40 | 50 | 50 | 50 | 50 |
| | second substrate | Second surface | <22.6 | <22.6 | <22.6 | <22.6 | <22.6 | <22.6 |
| | Laminating temperature (° C.) | | 20 | 20 | 20 | 80 | 100 | 20 |
| | Pressing force (kN/m) | | 15 | 15 | 15 | 15 | 15 | 15 |
| | Elastic modulus of second substrate | | 530 | 530 | 530 | 350 | 205 | 530 |
| | (N/mm²) | | | | | | | |
| | Tension applied to second substrate (N) | | 20 | 20 | 20 | 13 | 8 | 30 |
| | Stress applied to second substrate (MPa) | | 3.2 | 3.2 | 3.2 | 2.1 | 1.3 | 4.8 |
| | Elongation of second substrate (%) | | 0.6 | 0.6 | 0.6 | 0.6 | 0.6 | 0.9 |
| | Elastic modulus of first substrate (MPa) | | 5300 | 5300 | 5300 | 5100 | 5000 | 5300 |
| | Tension applied to first substrate (N) | | 200 | 200 | 200 | 190 | 190 | 200 |
| | Stress applied to first substrate (MPa) | | 32 | 32 | 32 | 31.2 | 31.2 | 32 |
| | Elongation of first substrate (%) | | 0.6 | 0.6 | 0.6 | 0.6 | 0.6 | 0.6 |
| | Elongation of second substrate- | | 0 | 0 | 0 | 0 | 0 | 0.3 |
| | elongation of first substrate | | | | | | | |
| | Evaluations | Peel strength (N/cm) | 0.2 | 0.3 | 0.35 | 0.5 | 1 | 0.2 |
| | | Peeling | ◯ | ◯ | ◯ | ◯ | ◯ | ◯ |
| | | Wrinkles of second | ◯ | ◯ | ◯ | ◯ | Δ | ◯ |
| | | substrate | | | | | | |
| | | Height of curling (mm) | 0 | 0 | 0 | 5 | 15 | 10 |
| Second | Construction of | Third substrate | Metal foil 1 | Metal foil 1 | Metal foil 1 | Metal foil 1 | Metal foil 1 | Metal foil 1 |
| step | laminated body II | Laminated body I | Laminated | Laminated | Laminated | Laminated | Laminated | Laminated |
| | | | body 1 | body 2 | body 3 | body 4 | body 5 | body 6 |
| | | Third substrate | — | — | — | — | — | — |
| | Laminating temperature (° C.) | | 360 | 360 | 360 | 360 | 360 | 360 |
| | Evaluations | Peel strength (N/cm) | 15 | 15 | 15 | 15 | 15 | 15 |
| | | Peeling | ◯ | ◯ | ◯ | ◯ | ◯ | ◯ |
| | | Wrinkles of second | ◯ | ◯ | ◯ | ◯ | Δ | Δ |
| | | substrate | | | | | | |
| | | Dimensional change | −0.10% | −0.10% | −0.10% | −0.10% | −0.10% | −0.10% |
| | | rate | | | | | | |

TABLE 2

| | | | Ex. 7 | Ex. 8 | Ex. 9 | Ex. 10 | Ex. 11 | Ex. 12 |
|---|---|---|---|---|---|---|---|---|
| Lamination method | | | Roll | Roll | Roll | Roll | Roll | Roll |
| | | | laminate | laminate | laminate | laminate | laminate | laminate |
| First | Laminated body I | | Laminated | Laminated | Laminated | Laminated | Laminated | Laminated |
| step | | | body 7 | body 8 | body 9 | body 10 | body 11 | body 12 |
| | Construction of | Second substrate | Fluororesin | Fluororesin | Fluororesin | Fluororesin | Fluororesin | Fluororesin |
| | laminated body I | | film 3 | film 3 | film 3 | film 3 | film 3 | film 3 |
| | | First substrate | Heat- | Heat- | Heat- | Heat- | Metal foil 1 | Heat- |
| | | | resistant | resistant | resistant | resistant | | resistant |
| | | | substrate 1 | substrate 1 | substrate 1 | substrate 1 | | substrate 1 |
| | | Second substrate | — | — | — | — | — | Fluororesin |
| | | | | | | | | film 3 |
| | Wetting tension of | First surface | 50 | 50 | 50 | 50 | 50 | 50 |
| | second substrate | Second surface | <22.6 | <22.6 | <22.6 | <22.6 | <22.6 | <22.6 |
| | Laminating temperature (° C.) | | 20 | 20 | 20 | 20 | 20 | 20 |
| | Pressing force (kN/m) | | 15 | 2 | 40 | 110 | 15 | 15 |
| | Elastic modulus of second substrate | | 530 | 530 | 530 | 530 | 530 | 530 |
| | (N/mm²) | | | | | | | |
| | Tension applied to second substrate (N) | | 20 | 20 | 20 | 20 | 10 | 20 |
| | Stress applied to second substrate (MPa) | | 3.2 | 3.2 | 3.2 | 3.2 | 1.6 | 3.2 |
| | Elongation of second substrate (%) | | 0.6 | 0.6 | 0.6 | 0.6 | 0.3 | 0.6 |
| | Elastic modulus of first substrate (MPa) | | 5300 | 5300 | 5300 | 5300 | 70000 | 5300 |
| | Tension applied to first substrate (N) | | 300 | 200 | 200 | 200 | 1000 | 200 |
| | Stress applied to first substrate (MPa) | | 48 | 32 | 32 | 32 | 160 | 32 |
| | Elongation of first substrate (%) | | 0.9 | 0.6 | 0.6 | 0.6 | 0.2 | 0.6 |
| | Elongation of second substrate- | | −0.3 | 0 | 0 | 0 | 0.1 | 0 |
| | elongation of first substrate | | | | | | | |
| | Evaluations | Peel strength (N/cm) | 0.2 | 0.05 | 0.6 | 0.7 | 0.2 | 0.35 |
| | | Peeling | ◯ | Δ | ◯ | ◯ | ◯ | ◯ |
| | | Wrinkles of second | ◯ | ◯ | ◯ | Δ | ◯ | ◯ |
| | | substrate | | | | | | |
| | | Height of curling (mm) | 10 | 0 | 0 | 0 | 5 | 0 |
| Second | Construction of | Third substrate | Metal foil 1 | Metal foil 1 | Metal foil 1 | Metal foil 1 | Heat- | Metal foil 1 |
| step | laminated body II | | | | | | resistant | |
| | | Laminated body I | Laminated | Laminated | Laminated | Laminated | Laminated | Laminated |
| | | | body 7 | body 8 | body 9 | body 10 | body 11 | body 12 |
| | | Third substrate | — | — | — | — | — | Metal foil 1 |
| | Laminating temperature (° C.) | | 360 | 360 | 360 | 360 | 360 | 360 |
| | Evaluations | Peel strength (N/cm) | 15 | 15 | 15 | 15 | 15 | 15 |
| | | Peeling | ◯ | Δ | ◯ | ◯ | ◯ | ◯ |
| | | Wrinkles of second | Δ | ◯ | ◯ | Δ | ◯ | ◯ |
| | | substrate | | | | | | |
| | | Dimensional change | −0.10% | −0.10% | −0.10% | −0.10% | −0.10% | −0.10% |
| | | rate | | | | | | |

TABLE 3

| | | | Ex. 13 | Ex. 14 | Ex. 15 | Ex. 16 | Ex. 17 |
|---|---|---|---|---|---|---|---|
| Lamination method | | | Roll | Roll | Roll | Roll | Roll |
| | | | laminate | laminate | laminate | laminate | laminate |
| First | Laminated body I | | Laminated | Laminated | Laminated | Laminated | Laminated |
| step | | | body 13 | body 14 | body 15 | body 16 | body 17 |
| | Construction of | Second substrate | Fluororesin | Fluororesin | Fluororesin | Fluororesin | Fluororesin |
| | laminated body I | | film 6 | film 7 | film 8 | film 9 | film 3 |
| | | First substrate | Heat- | Heat- | Heat- | Heat- | Heat- |
| | | | resistant | resistant | resistant | resistant | resistant |
| | | | substrate 1 | substrate 1 | substrate 1 | substrate 1 | substrate 4 |
| | | Second substrate | — | — | — | — | — |
| | Wetting tension of | First surface | 50 | 50 | 50 | 50 | 50 |
| | second substrate | Second surface | <22.6 | <22.6 | <22.6 | <22.6 | <22.6 |
| | Laminating temperature (° C.) | | 20 | 20 | 20 | 20 | 20 |
| | Pressing force (kN/m) | | 15 | 15 | 15 | 15 | 15 |
| | Elastic modulus of second substrate | | 530 | 530 | 530 | 530 | 530 |
| | (N/mm²) | | | | | | |
| | Tension applied to second substrate (N) | | 20 | 20 | 20 | 10 | 20 |
| | Stress applied to second substrate (MPa) | | 3.2 | 3.2 | 3.2 | 3.2 | 3.2 |
| | Elongation of second substrate (%) | | 0.6 | 0.6 | 0.6 | 0.6 | 0.6 |
| | Elastic modulus of first substrate (MPa) | | 5300 | 5300 | 5300 | 5300 | 3000 |
| | Tension applied to first substrate (N) | | 200 | 200 | 200 | 200 | 110 |
| | Stress applied to first substrate (MPa) | | 32 | 32 | 32 | 32 | 18 |
| | Elongation of first substrate (%) | | 0.6 | 0.6 | 0.6 | 0.6 | 0.6 |
| | Elongation of second substrate- | | 0 | 0 | 0 | 0 | 0 |
| | elongation of first substrate | | | | | | |
| | Evaluations | Peel strength (N/cm) | 0.35 | 0.35 | 0.35 | 0.35 | 0.35 |
| | | Peeling | ◯ | ◯ | ◯ | ◯ | ◯ |
| | | Wrinkles of second | ◯ | ◯ | ◯ | ◯ | ◯ |
| | | substrate | | | | | |
| | | Height of curling (mm) | 0 | 0 | 0 | 0 | 0 |
| Second | Construction of | Third substrate | Metal foil 1 | Metal foil 1 | Metal foil 1 | Metal foil 1 | Metal foil 1 |
| step | laminated body II | Laminated body I | Laminated | Laminated | Laminated | Laminated | Laminated |
| | | | body 13 | body 14 | body 15 | body 16 | body 17 |
| | | Third substrate | — | — | — | — | — |
| | Laminating temperature (° C.) | | 360 | 360 | 360 | 360 | 360 |
| | Evaluations | Peel strength (N/cm) | 17 | 13 | 9 | 15 | 15 |
| | | Peeling | ◯ | ◯ | ◯ | ◯ | ◯ |
| | | Wrinkles of second | ◯ | ◯ | ◯ | ◯ | ◯ |
| | | substrate | | | | | |
| | | Dimensional change | −0.10% | −0.10% | −0.10% | −0.10% | −0.10% |
| | | rate | | | | | |

TABLE 4

| | | | Ex. 18 | Ex. 19 | Ex. 20 | Ex. 21 | Ex. 22 |
|---|---|---|---|---|---|---|---|
| Lamination method | | | Roll | Roll | Roll | Roll | Double |
| | | | laminate | laminate | laminate | laminate | belt press |
| First | Laminated body I | | Laminated | Laminated | Laminated | Laminated | Laminated |
| step | | | body 18 | body 19 | body 20 | body 21 | body 22 |
| | Construction of | Second substrate | Fluororesin | Fluororesin | Fluororesin | Fluororesin | Fluororesin |
| | laminated body I | | film 3 | film 3 | film 11 | film 11 | film 3 |
| | | First substrate | Heat- | Heat- | Heat- | Heat- | Heat- |
| | | | resistant | resistant | resistant | resistant | resistant |
| | | | substrate 2 | substrate 3 | substrate 1 | substrate 4 | substrate 2 |
| | | Second substrate | — | — | — | — | — |
| | Wetting tension of | First surface | 50 | 50 | 50 | 50 | 50 |
| | second substrate | Second surface | <22.6 | <22.6 | <22.6 | <22.6 | <22.6 |
| | Laminating temperature (° C.) | | 20 | 20 | 20 | 20 | 20 |
| | Pressing force (kN/m) | | 15 | 15 | 15 | 15 | 15 |
| | Elastic modulus of second substrate | | 530 | 530 | 530 | 530 | 530 |
| | (N/mm²) | | | | | | |
| | Tension applied to second substrate (N) | | 20 | 20 | 10 | 20 | 10 |
| | Stress applied to second substrate (MPa) | | 3.2 | 3.2 | 3.2 | 3.2 | 3.2 |
| | Elongation of second substrate (%) | | 0.6 | 0.6 | 0.6 | 0.6 | 0.6 |
| | Elastic modulus of first substrate (MPa) | | 5300 | 5300 | 5300 | 3000 | 5300 |
| | Tension applied to first substrate (N) | | 200 | 200 | 200 | 110 | 200 |
| | Stress applied to first substrate (MPa) | | 32 | 32 | 32 | 18 | 32 |
| | Elongation of first substrate (%) | | 0.6 | 0.6 | 0.6 | 0.6 | 0.6 |
| | Elongation of second substrate- | | 0 | 0 | 0 | 0 | 0 |
| | elongation of first substrate | | | | | | |
| | Evaluations | Peel strength (N/cm) | 0.35 | 0.35 | 0.35 | 0.35 | 0.35 |
| | | Peeling | ◯ | ◯ | ◯ | ◯ | ◯ |
| | | Wrinkles of second | ◯ | ◯ | ◯ | ◯ | ◯ |
| | | substrate | | | | | |
| | | Height of curling (mm) | 0 | 0 | 0 | 0 | 0 |
| Second | Construction of | Third substrate | Metal foil 1 | Metal foil 1 | Metal foil 1 | Metal foil 1 | Metal foil 1 |
| step | laminated body II | Laminated body I | Laminated | Laminated | Laminated | Laminated | Laminated |
| | | | body 18 | body 19 | body 20 | body 21 | body 22 |
| | | Third substrate | — | — | — | — | — |
| | Laminating temperature (° C.) | | 360 | 360 | 305 | 305 | 360 |
| | Evaluations | Peel strength (N/cm) | 15 | 15 | 15 | 15 | 15 |
| | | Peeling | ◯ | ◯ | ◯ | ◯ | ◯ |
| | | Wrinkles of second | ◯ | ◯ | ◯ | ◯ | ◯ |
| | | substrate | | | | | |
| | | Dimensional change | −0.10% | −0.10% | −0.05% | −0.05% | −0.10% |
| | | rate | | | | | |

TABLE 5

| | | | Ex. 23 | Ex. 24 | Ex. 25 | Ex. 26 |
|---|---|---|---|---|---|---|
| Lamination method | | | Roll | Roll | Roll | Roll |
| | | | laminate | laminate | laminate | laminate |
| First | Laminated body I | | Laminated | Laminated | Laminated | Laminated |
| step | | | body 23 | body 24 | body 25 | body 26 |
| | Construction of | Second substrate | Fluororesin | Fluororesin | Fluororesin | Fluororesin |
| | laminated body I | | film 4 | film 5 | film 3 | film 10 |
| | | First substrate | Heat- | Heat- | Heat- | Heat- |
| | | | resistant | resistant | resistant | resistant |
| | | | substrate 1 | substrate 1 | substrate 1 | substrate 1 |
| | | Second substrate | — | — | — | — |
| | Wetting tension of | First surface | <22.6 | 70 | 50 | 30 |
| | second substrate | Second surface | <22.6 | <22.6 | <22.6 | 30 |
| | Laminating temperature (° C.) | | 20 | 20 | 120 | 20 |
| | Pressing force (kN/m) | | 15 | 15 | 15 | 15 |
| | Elastic modulus of second substrate | | 530 | 530 | 135 | 530 |
| | (N/mm²) | | | | | |
| | Tension applied to second substrate (N) | | 20 | 20 | 5 | 20 |
| | Stress applied to second substrate (MPa) | | 3.2 | 3.2 | 0.8 | 3.2 |
| | Elongation of second substrate (%) | | 0.6 | 0.6 | 0.6 | 0.6 |
| | Elastic modulus of first substrate (MPa) | | 5300 | 5300 | 4600 | 5300 |
| | Tension applied to first substrate (N) | | 200 | 200 | 170 | 200 |
| | Stress applied to first substrate (MPa) | | 32 | 32 | 27 | 32 |
| | Elongation of first substrate (%) | | 0.6 | 0.6 | 0.6 | 0.6 |
| | Elongation of second substrate- | | 0 | 0 | 0 | 0 |
| | elongation of first substrate | | | | | |
| | Evaluations | Peel strength (N/cm) | 0.00 | 0.01 | 1.5 | 0.2 |
| | | Peeling | × | × | ○ | × |
| | | Wrinkles of second | ○ | ○ | × | ○ |
| | | substrate | | | | |
| | | Height of curling (mm) | 0 | 0 | 30 | 0 |
| Second | Construction of | Third substrate | Metal foil 1 | Metal foil 1 | Metal foil 1 | Metal foil 1 |
| step | laminated body II | Laminated body I | Laminated | Laminated | Laminated | Laminated |
| | | | body 23 | body 24 | body 25 | body 26 |
| | | Third substrate | — | — | — | — |
| | Laminating temperature (° C.) | | 360 | 360 | 360 | 360 |
| | Evaluations | Peel strength (N/cm) | 15 | 15 | 15 | 15 |
| | | Peeling | × | × | ○ | × |
| | | Wrinkles of second | ○ | ○ | × | ○ |
| | | substrate | | | | |
| | | Dimensional change | −0.10% | −0.10% | −0.10% | −0.10% |
| | | rate | | | | |

TABLE 6

| | | | Ex. 27 | Ex. 28 | Ex. 29 | Ex. 30 | Ex. 31 |
|---|---|---|---|---|---|---|---|
| Lamination method | | | Roll | Roll | Roll | Roll | Roll |
| | | | laminate | laminate | laminate | laminate | laminate |
| First | Laminated body I | | Laminated | Laminated | Laminated | Laminated | Laminated |
| step | | | body 23 | body 24 | body 25 | body 26 | body 27 |
| | Construction of | Second substrate | Fluororesin | Fluororesin | Fluororesin | Fluororesin | Fluororesin |
| | laminated body I | | film 1 | film 1 | film 1 | film 1 | film 1 |
| | | First substrate | Heat- | Heat- | Heat- | Heat- | Heat- |
| | | | resistant | resistant | resistant | resistant | resistant |
| | | | substrate 5 | substrate 6 | substrate 7 | substrate 8 | substrate 9 |
| | | Second substrate | — | — | — | — | — |
| | Wetting tension of | First surface | 30 | 30 | 30 | 30 | 30 |
| | second substrate | Second surface | <22.6 | <22.6 | <22.6 | <22.6 | <22.6 |
| | Laminating temperature (° C.) | | 20 | 20 | 20 | 20 | 20 |
| | Pressing force (kN/m) | | 15 | 15 | 15 | 15 | 15 |
| | Elastic modulus of second substrate | | 530 | 530 | 530 | 530 | 530 |
| | (N/mm²) | | | | | | |
| | Tension applied to second substrate (N) | | 20 | 20 | 20 | 20 | 20 |
| | Stress applied to second substrate (MPa) | | 3.2 | 3.2 | 3.2 | 3.2 | 3.2 |
| | Elongation of second substrate (%) | | 0.6 | 0.6 | 0.6 | 0.6 | 0.6 |
| | Elastic modulus of first substrate (MPa) | | 5300 | 5300 | 5300 | 3000 | 3000 |
| | Tension applied to first substrate (N) | | 200 | 200 | 200 | 110 | 110 |
| | Stress applied to first substrate (MPa) | | 32 | 32 | 32 | 18 | 18 |
| | Elongation of first substrate (%) | | 0.6 | 0.6 | 0.6 | 0.6 | 0.6 |
| | Elongation of second substrate- | | 0 | 0 | 0 | 0 | 0 |
| | elongation of first substrate | | | | | | |
| | Evaluations | Peel strength (N/cm) | 0.2 | 0.2 | 0.2 | 0.35 | 0.35 |
| | | Peeling | ◯ | ◯ | ◯ | ◯ | ◯ |
| | | Wrinkles of second | ◯ | ◯ | ◯ | ◯ | ◯ |
| | | substrate | | | | | |
| | | Height of curling (mm) | 0 | 0 | 0 | 0 | 0 |
| Second | Construction of | Third substrate | Metal foil 1 | Metal foil 1 | Metal foil 1 | Metal foil 1 | Metal foil 1 |
| step | laminated body II | Laminated body I | Laminated | Laminated | Laminated | Laminated | Laminated |
| | | | body 23 | body 24 | body 25 | body 26 | body 27 |
| | | Third substrate | — | — | — | — | — |
| | Laminating temperature (° C.) | | 360 | 360 | 360 | 360 | 360 |
| | Evaluations | Peel strength (N/cm) | 17 | 20 | 23 | 18 | 18 |
| | | Peeling | ◯ | ◯ | ◯ | ◯ | Δ |
| | | Wrinkles of second | ◯ | ◯ | ◯ | ◯ | ◯ |
| | | substrate | | | | | |
| | | Dimensional change | −0.10% | −0.10% | −0.10% | −0.10% | −0.10% |
| | | rate | | | | | |

In Ex. 1 to 22, occurrence of wrinkles and delamination was suppressed. Further, curling of the laminated body I was suppressed. In Ex. 23, since the wetting tension of the first surface of the second substrate was less than 30 mN/m, the adhesion strength between the first substrate and the second substrate was low, and the evaluation result of peeling was poor. The peeled portion of the laminated body I did not disappear even in the second step, and thus, was considered to have become as peeling of the laminated body II.

In Ex. 24, since the wetting tension of the first surface of the second substrate was more than 60 mN/m, the adhesion strength between the first substrate and the second substrate was low, and the evaluation result of peeling was poor. The peeled portion of the laminated body I did not disappear even in the second step, and thus was considered to have become as peeling of the laminated body II. At the first surface of the second substrate, the corona discharge treatment was too strong, whereby a low molecular weight substance formed by decomposition of the resin was deposited to form a WBL (Weak Boundary Layer), which is considered to have inhibited the adhesion with the first substrate.

In Ex. 25, since the laminating temperature was more than 100° C., wrinkles were formed in the second substrate, and the evaluation result of curling was also poor. At the above laminating temperature, it is considered that due to the thermal expansion of the second substrate, wrinkles occurred, and as the wrinkles were caught in the laminating rolls and became wrinkles with bent marks. Further, it is considered that after lamination, as the temperature of the laminated body I decreased, curling became stronger. Further, it is considered that due to the wrinkles and strong curling imparted to the laminated body I, wrinkles occurred also in the second step.

In Ex. 26, since the wetting tension of the first surface and the wetting tension of the second surface of the second substrate were the same, the evaluation result of peeling was poor. In this Ex., it is considered that the adhesion between the laminating rolls and the second substrate became sufficiently high relative to the adhesion between the first substrate and the second substrate, whereby at the time when departing from the lamination roll, the second substrate partially stuck to the roll, thus resulting in peeling. The peeled portion of the laminated body I did not disappear even in the second step, and thus was considered to have become as peeling of the laminated body II.

In Ex. 27 to 30, adhesion between the layers of the laminated body II was improved. This is considered to be because since the surface treatment was applied to the heat-resistant substrates 5 to 8 being the first substrate, the chemical and physical bonding between the first substrate and the second substrate after the second step became firm. In Ex. 31, since the heat-resistant substrate having a higher water absorption rate, was used, the evaluation of peeling became “acceptable”. This is considered to be because the moisture in the heat-resistant substrate was volatilized during the second step, to form slight air bubbles, which remained between the layers of the laminated body II.

### INDUSTRIAL APPLICABILITY

The laminated body produced by the present invention can be suitably used as a substrate of a flexible printed circuit board, an electromagnetic wave shielding tape for a cable, a bag for a lithium ion battery of a laminate type, etc.

### REFERENCE SYMBOLS

10, 10A: laminated body (laminated body I), 12: heat-resistant substrate (first substrate), 14: second substrate, 14a: first surface, 14b: second surface, 16: metal foil layer (third substrate), 20, 20A: laminated body (laminated body II), 100, 200: roll laminating apparatus, 101: laminating roll, 103: first feeding roll, 105: second feeding roll, 107: third feeding roll

What is claimed is:

1. A method for producing a laminated body, which comprises disposing, on one side or both sides of a first substrate composed of either one or both of a heat-resistant substrate layer and a metal foil layer, a second substrate containing a fluororesin and having a first surface of which the wetting tension as measured in accordance with JIS K6768:1999 is from 30 to 60 mN/m and a second surface of which said wetting tension is smaller by at least 2 mN/m than the wetting tension of the first surface, so that said first surface faces said first substrate side, and, while transporting the first substrate and the second substrate, pressing them in the thickness direction at a temperature T₁ of from 0 to 100° C. for lamination, to obtain a laminated body I wherein the first substrate and the second substrate are directly laminated.

2. The method for producing a laminated body according to claim 1, which comprises disposing, on the second substrate of the laminated body I, a third substrate composed of either one or both of a heat-resistant substrate layer and a metal foil layer, and, while transporting the laminated body I and the third substrate, pressing them in the thickness direction at a temperature T₂ of at least the melting point of the fluororesin for lamination, to obtain a laminated body II wherein the laminated body I and the third substrate are directly laminated.

3. The method for producing a laminated body according to claim 1, wherein the control of the wetting tension of the second substrate of the laminated body I is carried out by surface treatment, and the method for the surface treatment is by corona discharge treatment or vacuum plasma treatment.

4. The method for producing a laminated body according to claim 1, wherein at the time of transporting the first substrate and the second substrate, the elongation obtainable by the following formula 1, of each of the first substrate and the second substrate, is made to be from 0.05 to 1.0%, and the difference in the elongation between the first substrate and the second substrate is made to be at most 0.3%:
elongation (%)={tension (N) applied to the substrate during transportation/cross-sectional area (mm²) of the substrate in a direction perpendicular to the transporting direction}/elastic modulus (N/mm²) of the substrate at a temperature T₁×100 Formula 1:

5. The method for producing a laminated body according to claim 1, wherein the pressing force at the time of laminating the first substrate and the second substrate is from 3 to 100 kN/m.

6. The method for producing a laminated body according to claim 1, wherein at either one or both of a terminal group of the main chain and a pendant group of the main chain of the fluororesin, at least one type of functional group selected from the group consisting of a carbonyl group-containing group, a hydroxy group, an epoxy group, an amide group, an amino group and an isocyanate group is present.

7. The method for producing a laminated body according to claim 1, wherein the first substrate is a heat-resistant resin film, and the water contact angle of its surface as measured by the sessile drop method described in JIS R6769:1999, is from 5° to 60°.

8. The method for producing a laminated body according to claim 7, wherein the heat-resistant resin film is a film which is surface-treated by corona discharge treatment, atmospheric pressure plasma treatment or vacuum plasma treatment.

9. The method for producing a laminated body according to claim 7, wherein the water absorption of the heat-resistant resin film is at most 1.5%.

10. A laminated body in which, on one side or both sides of a first substrate composed of either one or both of a heat-resistant substrate layer and a metal foil layer, a second substrate containing a fluororesin and having a first surface of which the wetting tension as measured in accordance with JIS K6768:1999 is from 30 to 60 mN/m and a second surface of which said wetting tension is smaller by at least 2 mN/m than the wetting tension of the first surface, is laminated directly, so that the first surface faces the first substrate side.

11. A method for producing a flexible printed circuit board, which comprises obtaining the laminated body II of which at least one of the outermost layers is a metal foil layer, by the method for producing a laminated body as defined in claim 2, and removing a portion of the metal foil layer of the outermost layers by etching to form a patterned circuit.
